(19) United States
(12) Patent Application Publication
(10) Pub. No.: US 2022/0332733 A1
(43) Pub. Date: Oct. 20, 2022

(54) MATERIAL FOR WAVELENGTH CONVERSION, WAVELENGTH CONVERSION MEMBER, LIGHT EMITTING DEVICE, AND COMPOUND USED FOR SAME

(71) Applicant: FUJIFILM Corporation, Tokyo (JP)

(72) Inventor: Kousuke WATANABE, Kanagawa (JP)

(73) Assignee: FUJIFILM Corporation, Tokyo (JP)

(21) Appl. No.: 17/693,408

(22) Filed: Mar. 13, 2022

(30) Foreign Application Priority Data
Apr. 8, 2021 (JP) 2021-065685

(51) Int. Cl. C07F 5/02; H01L 51/00; H01L 33/50

(52) U.S. Cl. CPC C07F 5/022; H01L 51/008; H01L 51/0054; H01L 51/0072; H01L 33/502

(57) ABSTRACT

Provided are a material for wavelength conversion formed of a dipyrromethene boron complex compound having excellent solubility in a medium and exhibiting a sufficiently large molar absorption coefficient, a wavelength conversion member, a light emitting device, and a compound.

A material for wavelength conversion containing a compound represented by General Formula (1), a wavelength conversion member formed of the material for wavelength conversion, a light emitting device, and a compound.

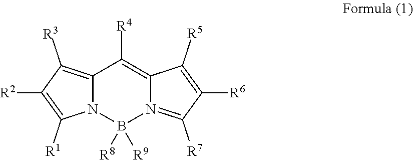

In the formula, R¹ to R⁷ each represent a hydrogen atom or a substituent, and R⁸ and R⁹ each represent a specific substituent.

At least one of R¹, . . . , or R⁹ has a partial structure represented by Formula (A).

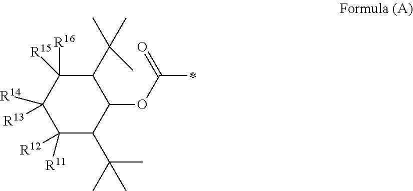

In the formula, R¹¹ to R¹⁶ each represent a hydrogen atom or an alkyl group, and the symbol * represents a bonding site.

### CROSS-REFERENCE TO RELATED APPLICATION

The present application claims priority under 35 U.S.C. § 119 to Japanese Patent Application No. 2021-065685, filed on Apr. 8, 2021. The above application is hereby expressly incorporated by reference, in its entirety, into the present application.

### BACKGROUND OF THE INVENTION

### 1. Field of the Invention

The present invention relates to a material for wavelength conversion, a wavelength conversion member, a light emitting device, and a compound used for the same.

### 2. Description of the Related Art

In display devices such as various displays, a light emitting diode (LED) emitting white light is widely used. In recent years, there has been a growing interest in the issue of energy saving, and, accordingly, lighting devices such as fluorescent lamps using a white LED have rapidly become widespread.

Usually, a white LED is constituted with a combination of an LED and a phosphor. Generally, this phosphor is formed of a material for wavelength conversion containing a fluorescent compound which has a function or property of absorbing light (incoming rays) of a specific wavelength radiated from an LED and emitting light (outgoing rays) of a specific wavelength different from the incoming rays (hereinafter, referred to as wavelength conversion characteristics), an optional resin, and the like. Among fluorescent compounds, organic fluorescent compounds are generally superior to inorganic fluorescent compounds in wavelength conversion efficiency.

As a material for wavelength conversion formed of such an organic fluorescent compound, a material containing a dipyrromethene boron complex compound in which a dipyrromethene compound is coordinated to a boron atom in a bidentate manner, and a resin has been proposed. For example, WO2016/190283A describes, as a dipyrromethene boron complex compound represented by General Formula (1), a color conversion composition (material for wavelength conversion) containing: a compound having an electron withdrawing group introduced therein or a compound in which R⁷ in General Formula (1) is an aryl group or a heteroaryl group; and a binder resin.

### SUMMARY OF THE INVENTION

In addition, although not described as a material for wavelength conversion, a coloring composition containing a dipyrromethene-based complex compound represented by General Formula (I) and an infrared absorbing compound having an absorption maximum at a wavelength of 700 nm or more, and a color filter formed of the composition are described in JP2012-77153A.

In recent years, it has been required to further improve wavelength conversion characteristics by improving the wavelength conversion efficiency of the material for wavelength conversion or increasing the luminance.

A dipyrromethene boron complex compound used for the material for wavelength conversion is required to have sufficient solubility in a medium (for example, solvent, resin, or monomer) from the viewpoint of developing a material for wavelength conversion having higher luminance. In a case where a dipyrromethene boron complex compound having high solubility is used, deterioration of performance due to aggregation or deterioration of manufacturing suitability due to precipitation rarely occurs in the preparation of a material for wavelength conversion. That is, the dipyrromethene boron complex compound can be allowed to uniformly exist at a high concentration in a material for wavelength conversion to be obtained. As a result, it is possible to obtain a material for wavelength conversion having high luminance. Furthermore, in a case where the solubility is low, it becomes necessary to change the dissolution conditions such as microparticulation by heating or a treatment using ultrasonic waves or the like, or to remove insoluble components by a treatment such as filter filtration, and thus there is a problem in that the productivity of a material for wavelength conversion may be reduced. In addition, increasing the emission efficiency (wavelength conversion efficiency) which can be expressed by the product of the molar absorption coefficient and the quantum yield is also an important factor in increasing the luminance of a material for wavelength conversion.

However, on the basis of the results of the study conducted by the inventors of the present invention, it has been found that the dipyrromethene boron complex compound used for the material for wavelength conversion described in WO2016/190283A is not sufficiently soluble and does not have a large molar absorption coefficient, and thus there is room for improvement.

An object of the present invention is to provide a material for wavelength conversion formed of a dipyrromethene boron complex compound having excellent solubility in a medium (hereinafter, also simply referred to as “solubility”) and exhibiting a sufficiently large molar absorption coefficient. Another object of the present invention is to provide a dipyrromethene boron complex compound having excellent solubility and exhibiting a sufficiently large molar absorption coefficient. Still another object of the present invention is to provide a wavelength conversion member formed of the material for wavelength conversion and a light emitting device.

The present inventor has found that a dipyrromethene boron complex compound having a specific structure in which a specific substituent having both hydrophobicity and bulkiness is introduced on a dipyrromethene skeleton has excellent solubility and an increased molar absorption coefficient. Based on these findings, the inventors further repeated examinations and have accomplished the present invention.

That is, the objects of the present invention have been achieved by the following units.

[1] A material for wavelength conversion containing: a compound represented by General Formula (1).

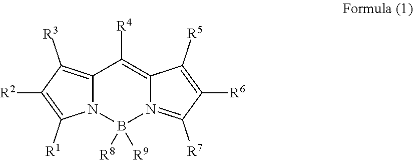

In the formula, R¹ to R⁷ each represent a hydrogen atom or a substituent. R⁸ and R⁹ each represent an alkyl group, a cycloalkyl group, an aliphatic heterocyclic group, an alkenyl group, a cycloalkenyl group, an alkynyl group, a hydroxy group, a sulfanyl group, an alkoxy group, an alkylthio group, an aryloxy group, an arylthio group, an aryl group, a heteroaryl group, a cyano group, or a halogen atom.

At least one of R¹, . . . , or R⁹ has a partial structure represented by Formula (A).

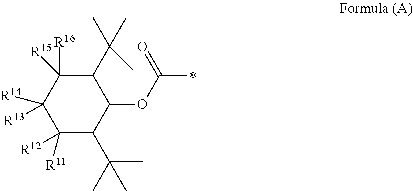

In the formula, R¹¹ to R¹⁶ each represent a hydrogen atom or an alkyl group, and the symbol * represents a bonding site.

[2] The material for wavelength conversion according to [1], in which the compound represented by General Formula (1) is a compound represented by General Formula (2) or (3).

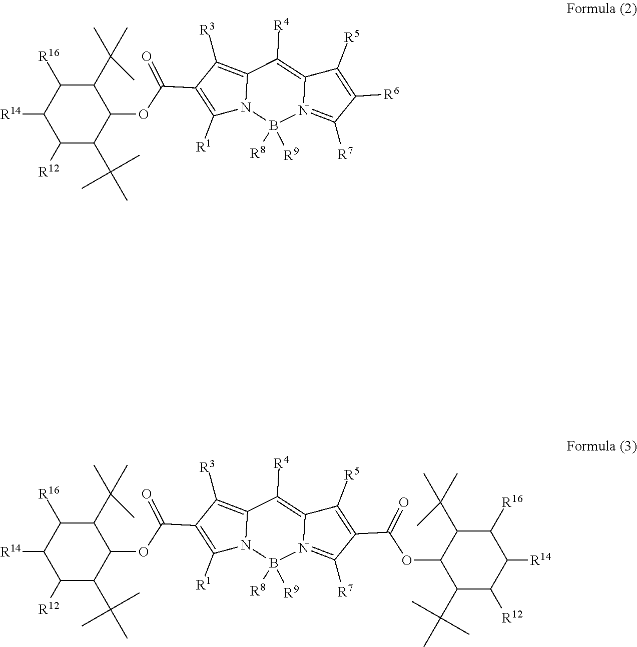

In the formula, R¹, R³ to R⁹, R¹², R¹⁴, and R¹⁶ have the same definition as R¹, R³ to R⁹, R¹², R¹⁴, and R¹⁶ described above, respectively.

[3] The material for wavelength conversion according to [1] or [2], in which at least one of R⁸ or R⁹ is a halogenated alkyl group, a halogenated alkyloxy group, or a cyano group.

[4] A wavelength conversion member having: a wavelength conversion portion formed of the material for wavelength conversion according to any one of [1] to [3].

[5] A light emitting device having: a light source; and the wavelength conversion member according to [4], which converts light emitted from the light source.

[6] The light emitting device according to [5], in which the light emitting device is a display device or a lighting device.

[7] The light emitting device according to [6], in which the display device is a liquid crystal display device.

[8] A compound represented by General Formula (1A).

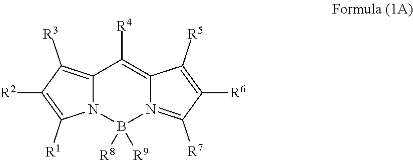

In the formula, R¹ to R⁷ each represent a hydrogen atom or a substituent. R⁸ and R⁹ each represent an alkyl group, a cycloalkyl group, an aliphatic heterocyclic group, an alkenyl group, a cycloalkenyl group, an alkynyl group, a hydroxy group, a sulfanyl group, an alkoxy group, an alkylthio group, an aryloxy group, an arylthio group, an aryl group, a heteroaryl group, a cyano group, or a halogen atom.

At least one of R⁸ or R⁹ is a halogenated alkyl group, a halogenated alkyloxy group, or a cyano group, and at least one of R¹, . . . , or R⁹ has a partial structure represented by Formula (A).

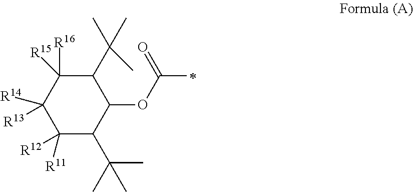

In the formula, R¹¹ to R¹⁶ each represent a hydrogen atom or an alkyl group, and the symbol * represents a bonding site.

[9] The compound according to [8], in which the compound is a compound represented by General Formula (2A) or (3A).

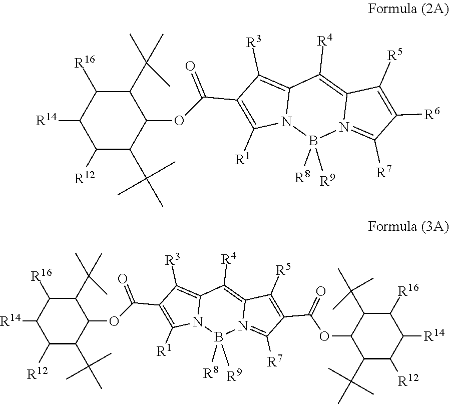

In the formula, R¹, R³ to R⁹, R¹², R¹⁴, and R¹⁶ have the same definition as R¹, R³ to R⁹, R¹², R¹⁴, and R¹⁶ described above, respectively.

[10] The compound according to [8] or [9], in which at least one of R⁸ or R⁹ is a halogenated alkyl group or a cyano group.

In the present invention, “wavelength conversion” means converting (incoming) light of a specific wavelength into (outgoing) light of a wavelength different from the specific wavelength (usually, a wavelength longer than the specific wavelength). “Wavelength conversion” is also referred to as “color conversion”.

The material for wavelength conversion according to an aspect of the present invention, the wavelength conversion member formed of the material for wavelength conversion, and the light emitting device are provided using a dipyrromethene boron complex compound having excellent solubility and exhibiting a sufficiently large molar absorption coefficient, and have excellent emission efficiency. In addition, the dipyrromethene boron complex compound of the present invention has excellent solubility and exhibits a sufficiently large molar absorption coefficient.

### DESCRIPTION OF THE PREFERRED EMBODIMENTS

In the present invention, in a case where there is a plurality of substituents, linking groups, or the like (hereinafter, described as substituents or the like) marked with a specific reference sign or formula, or in a case where a plurality of substituents or the like is simultaneously specified, unless otherwise specified, the substituents or the like may be the same as or different from each other. The same is true of a case where the number of substituents or the like is specified. Furthermore, in a case where a plurality of substituents or the like is close (particularly, adjacent) to each other, unless otherwise specified, the substituents or the like may be linked to each other to form a ring. In addition, unless otherwise specified, a ring such as an alicyclic ring, an aromatic ring, or a heterocyclic ring may be further fused to form a fused ring.

In the present invention, in a case where a molecule has an E-type double bond and a Z-type double bond, unless otherwise specified, the molecule may be either an E isomer or a Z isomer or may be a mixture thereof.

In the present invention, regarding each of components (compound represented by General Formula (1), resin, and components other than the compound and the resin) capable of constituting a material for wavelength conversion, one kind or two or more kinds may be contained in the material for wavelength conversion unless otherwise specified. The same is true of a case of components capable of constituting a member for wavelength conversion.

In the present invention, in calculating the content of each component in the material for wavelength conversion, the solid content means components other than a solvent.

In the present invention, the term “compound” (including a complex) means a compound including a salt and ion thereof. Furthermore, as long as the effects of the present invention are not impaired, the term also means a compound having partially modified structure. In addition, for a compound which is not specified regarding whether or not the compound is substituted, as long as the effects of the present invention are not impaired, the term means that the compound may have any substituent. The same is true of substituents and linking groups.

In the present invention, in a case where the number of carbon atoms of a certain group is specified, the number of carbon atoms means the number of carbon atoms in the entire group unless otherwise specified in the present invention or the present specification. That is, in a case where this group is in a form further having a substituent, the number of carbon atoms means the number of carbon atoms in the entire group including this substituent.

Furthermore, in the present invention, a range of numerical values described using “to” means a range including numerical values described before and after “to” as a lower limit and an upper limit.

In the present invention, a composition includes a mixture of components having a constant concentration (evenly dispersed components) and a mixture of components having a concentration that changes within a range in which the intended wavelength conversion function is not impaired.

### Material for Wavelength Conversion

A material for wavelength conversion according to the embodiment of the present invention contains a compound represented by General Formula (1) (dipyrromethene boron complex compound). The compound represented by General Formula (1) is a fluorescent compound, and the material for wavelength conversion according to the embodiment of the present invention converts the wavelength of incoming rays into light of a longer wavelength by wavelength conversion characteristics of the compound represented by General Formula (1).

The same is true of a wavelength conversion portion to be described later, formed of the material for wavelength conversion according to the embodiment of the present invention, and the wavelength conversion portion of the present invention converts the wavelength of incoming rays into light of a longer wavelength by wavelength conversion characteristics of the compound represented by Formula (1).

Usually, the material for wavelength conversion according to the embodiment of the present invention does not contain a compound (for example, infrared absorbing compound) absorbing the light emission (fluorescence) of the compound represented by General Formula (1). The material for wavelength conversion according to the embodiment of the present invention may be in any one of a solution form, a dispersion liquid form, a semisolid (slurry or the like) form, or a solid form. The material for wavelength conversion according to the embodiment of the present invention is preferably in a form in which all the components are uniformly mixed, that is, a form of a composition. Examples of components other than the compound represented by General Formula (1) contained in the material for wavelength conversion according to the embodiment of the present invention include resins, raw material monomers, solvents, and other additives to be described later. Details of each form are as described later in the method of preparing a material for wavelength conversion according to the embodiment of the present invention. The material for wavelength conversion according to the embodiment of the present invention can be stably stored by controlling storage conditions such as light shielding and low temperature as needed.

### Compound Represented by General Formula (1)

The material for wavelength conversion according to the embodiment of the present invention contains a compound represented by General Formula (1).

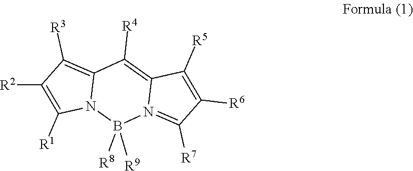

In the formula, R¹ to R⁷ each represent a hydrogen atom or a substituent. R⁸ and R⁹ each represent an alkyl group, a cycloalkyl group, an aliphatic heterocyclic group, an alkenyl group, a cycloalkenyl group, an alkynyl group, a hydroxy group, a sulfanyl group, an alkoxy group, an alkylthio group, an aryloxy group, an arylthio group, an aryl group, a heteroaryl group, a cyano group, or a halogen atom.

At least one of R¹, . . . , or R⁹ has a partial structure represented by Formula (A).

### (i) R¹ to R⁷

R¹ to R⁷ each independently represent a hydrogen atom or a substituent.

Examples of the substituent which can be adopted as R¹ to R⁷ include substituents in a substituent group T to be described later.

Among the examples, preferable examples of R¹ and R⁷ include an alkyl group, an aryl group, an amino group, and an acylamino group.

Examples of the substituent that the above-described alkyl group, aryl group, amino group, and acylamino group may have include substituents in the substituent group T to be described later, such as a sulfonylamino group.

Among the examples, R¹ to R⁷ each are more preferably an amino group, and even more preferably —NH₂.

Among the examples, preferable examples of R² and R⁶ include an alkoxycarbonyl group and a cyano group.

Preferable examples of the alkoxycarbonyl group include a partial structure represented by Formula (A).

Among the examples, it is more preferable that R² and R⁶ have a partial structure represented by Formula (A) as a group.

Among the examples, R³ and R⁵ each are preferably an alkyl group or an aryl group.

Among the examples, R⁴ is preferably a hydrogen atom, an alkyl group, an aryl group, or a cyano group.

Examples of the substituent that the above-described alkyl group and aryl group described above may have include substituents in the substituent group T to be described later, such as a halogen atom (preferably fluorine atom), a halogenated alkyl group, an alkyl group, an alkoxy group, an alkylaryl group, and an aryl group.

Among the examples, R⁴ is more preferably a hydrogen atom or an alkyl group.

### (ii) R⁸ and R⁹

R⁸ and R⁹ each represent an alkyl group, a cycloalkyl group, an aliphatic heterocyclic group, an alkenyl group, a cycloalkenyl group, an alkynyl group, a hydroxy group, a sulfanyl group, an alkoxy group, an alkylthio group, an aryloxy group, an arylthio group, an aryl group, a heteroaryl group, a cyano group, or a halogen atom (preferably fluorine atom), and an alkyl group, an alkenyl group, an alkoxy group, an aryl group, a cyano group, or a halogen atom is preferable.

Examples of the alkyl group, cycloalkyl group, aliphatic heterocyclic group, alkenyl group, cycloalkenyl group, alkynyl group, hydroxy group, sulfanyl group, alkoxy group, alkylthio group, aryloxy group, arylthio group, aryl group, heteroaryl group, cyano group, or halogen atom which can be adopted as R⁸ or R⁹ include an alkyl group, a cycloalkyl group, an aliphatic heterocyclic group, an alkenyl group, a cycloalkenyl group, an alkynyl group, a hydroxy group, a sulfanyl group, an alkoxy group, an alkylthio group, an aryloxy group, an arylthio group, an aryl group, a heteroaryl group, a cyano group, or a halogen atom in the substituent group T to be described later.

Examples of the substituent that the above-described alkyl group, cycloalkyl group, aliphatic heterocyclic group, alkenyl group, cycloalkenyl group, alkynyl group, alkoxy group, alkylthio group, aryloxy group, arylthio group, aryl group, and heteroaryl group may have include substituents in the substituent group T to be described later, such as a halogen atom (preferably fluorine atom) and an aryl group.

At least one of R⁸ or R⁹ is preferably a halogenated alkyl group, a halogenated alkyloxy group, or a cyano group, more preferably a halogenated alkyl group or a cyano group, and even more preferably a halogenated alkyl group.

### (iii) Partial Structure Represented by Formula (A)

At least one of R¹, . . . , or R⁹ has a partial structure represented by Formula (A).

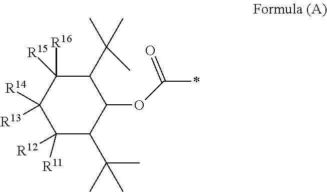

In the formula, R¹¹ to R¹⁶ each represent a hydrogen atom or an alkyl group, and the symbol * represents a bonding site.

Examples of the alkyl group which can be adopted as R¹¹ to R¹⁶ include alkyl groups in the substituent group T to be described later.

In combination of R¹¹ to R¹⁶, it is preferable that R¹¹, R¹³, and R¹⁵ each are a hydrogen atom and R¹², R¹⁴, and R¹⁶ each are a hydrogen atom or an alkyl group, it is more preferable that R¹¹, R¹², and R¹⁴ to R¹⁶ each are a hydrogen atom and R¹³ is a hydrogen atom or an alkyl group, and it is even more preferable that R¹¹, R¹², and R¹⁴ to R¹⁶ each are a hydrogen atom and R¹³ is a hydrogen atom or an alkyl group having 1 to 8 carbon atoms.

The form in which at least one of R¹, . . . , or R⁹ has a partial structure represented by Formula (A) may be any one of a form in which each of R¹ to R⁹ itself is a group represented by Formula (A) (that is, a form in which * in Formula (A) is a bonding site of R¹ to R⁹) or a form in which the substituent which can be adopted as R¹ to R⁹ further has a partial structure represented by Formula (A) as a substituent (that is, a form in which * in Formula (A) is a bonding site which is substituted for a substituent which can be adopted as R¹ to R⁹), and is preferably a form in which each of R¹ to R⁹ itself is a group represented by Formula (A).

Preferable examples of the form in which the substituent which can be adopted as R¹ to R⁹ further has a partial structure represented by Formula (A) as a substituent include a form in which an alkyl group, an aryl group, an alkoxy group, or a heteroaryl group further has a partial structure represented by Formula (A) as a substituent.

Among R¹ to R⁹ described above, at least one of R² or R⁶ preferably has a partial structure represented by Formula (A). More preferably, both R² and R⁶ have a partial structure represented by Formula (A).

The compound represented by General Formula (1) is preferably a compound represented by General Formula (2) or (3), and more preferably a compound represented by General Formula (3).

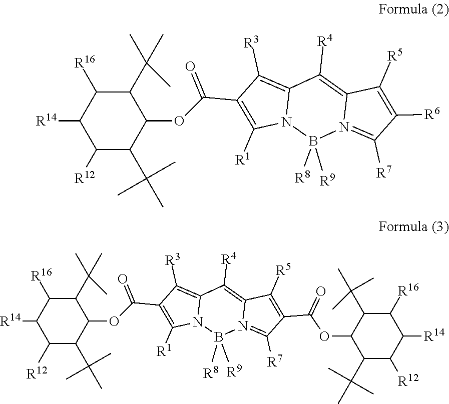

In the formula, R¹, R³ to R⁹, R¹², R¹⁴, and R¹⁶ have the same definition as R¹, R³ to R⁹, R¹², R¹⁴, and R¹⁶ in General Formula (1), respectively.

### Compound Represented by General Formula (1A)

The compound according to the embodiment of the present invention is a compound represented by General Formula (1A).

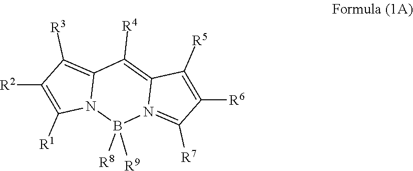

In the formula, R¹ to R⁷ each represent a hydrogen atom or a substituent. R⁸ and R⁹ each represent an alkyl group, a cycloalkyl group, an aliphatic heterocyclic group, an alkenyl group, a cycloalkenyl group, an alkynyl group, a hydroxy group, a sulfanyl group, an alkoxy group, an alkylthio group, an aryloxy group, an arylthio group, an aryl group, a heteroaryl group, a cyano group, or a halogen atom.

At least one of R⁸ or R⁹ is a halogenated alkyl group, a halogenated alkyloxy group, or a cyano group, and at least one of R¹, . . . , or R⁹ has a partial structure represented by Formula (A).

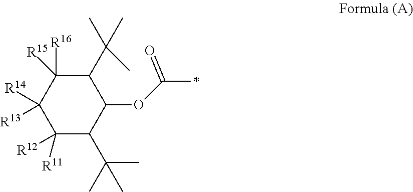

In the formula, R¹¹ to R¹⁶ each represent a hydrogen atom or an alkyl group, and the symbol * represents a bonding site.

The compound represented by General Formula (1A) is the same as the compound represented by General Formula (1), except that at least one of R⁸ or R⁹ is a halogenated alkyl group, a halogenated alkyloxy group, or a cyano group. Therefore, as R¹ to R⁹ in General Formula (1A) and the partial structure represented by Formula (A), the description of R¹ to R⁹ in General Formula (1) and the partial structure represented by Formula (A) can be applied, except that at least one of R⁸ or R⁹ is a halogenated alkyl group, a halogenated alkyloxy group, or a cyano group.

The compound represented by General Formula (1A) is preferably a compound represented by General Formula (2A) or (3A).

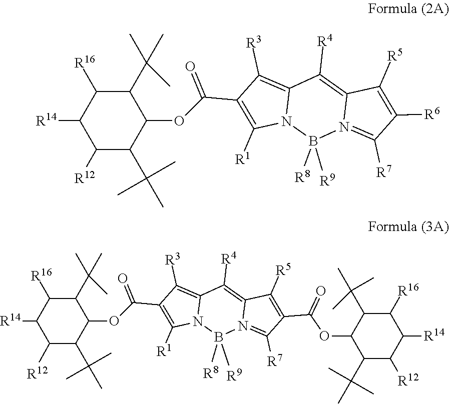

In the formula, R¹, R³ to R⁹, R¹², R¹⁴, and R¹⁶ have the same definition as R¹, R³ to R⁹, R¹², R¹⁴, and R¹⁶ in General Formula (1A), respectively.

### Substituent Group T

In the present invention, as substituents, for example, substituents selected from the following substituent group T are preferable.

Furthermore, in the present specification, in a case where only the term “substituent” is mentioned, the substituent group T may be referred to. In a case where a substituent is described as each group such as an alkyl group, the corresponding group in the substituent group T may be applied.

In addition, in the present specification, in a case where an alkyl group is specially described as a cyclic (cyclo) alkyl group, the alkyl group means both the linear alkyl group and branched alkyl group. On the other hand, unless an alkyl group is specially described as cyclic alkyl group and unless otherwise specified, the alkyl group means all of a linear alkyl group, a branched alkyl group, and a cycloalkyl group. The same is true of the groups (an alkoxy group, an alkylthio group, an alkenyloxy group, and the like) including groups (an alkyl group, an alkenyl group, an alkynyl group, and the like) which can have a cyclic structure and the compounds including groups which can have a cyclic structure. In a case where a group can form a cyclic skeleton, the lower limit of the number of atoms in the group forming the cyclic skeleton is equal to or greater than 3 and preferably equal to or greater than 5, regardless of the lower limit of the number of atoms specifically described below regarding the group which can have such a structure.

In the following description of the substituent group T, for example, just as “alkyl group” and “cycloalkyl group”, a group having a linear or branched structure and a group having a cyclic structure are separately described in some cases such that they are clearly distinguished from each other.

Examples of the groups included in the substituent group T include the following groups:

an alkyl group (preferably having 1 to 20 carbon atoms, such as methyl, ethyl, isopropyl, t-butyl, pentyl, heptyl, 1-ethylpentyl, benzyl, 2-ethoxyethyl, 1-carboxymethyl, and trifluoromethyl), an alkenyl group (preferably having 2 to 20 carbon atoms, such as vinyl, allyl, and oleyl), an alkynyl group (preferably having 2 to 20 carbon atoms, such as ethynyl, butadiynyl, and phenylethynyl), a cycloalkyl group (preferably having 3 to 20 carbon atoms, such as cyclopropyl, cyclopentyl, cyclohexyl, and 4-methylcyclohexyl), a cycloalkenyl group (preferably having 5 to 20 carbon atoms, such as cyclopentenyl and cyclohexenyl), an aryl group (preferably having 6 to 26 carbon atoms, such as phenyl, 1-naphthyl, 4-methoxyphenyl, 2-chlorophenyl, and 3-methylphenyl), a heterocyclic group (preferably having 2 to 20 carbon atoms, and more preferably a 5-membered or 6-membered heterocyclic group having at least one oxygen atom, sulfur atom, or a nitrogen atom, such as 2-pyridyl, 4-pyridyl, 2-imidazolyl, 2-benzimidazolyl, 2-thiazolyl, and 2-oxazolyl), an alkoxy group (preferably having 1 to 20 carbon atoms, such as methoxy, ethoxy, isopropyloxy, and benzyloxy), an alkenyloxy group (preferably having 2 to 20 carbon atoms, such as vinyloxy and allyloxy), an alkynyloxy group (preferably having 2 to 20 carbon atoms, such as 2-propynyloxy and 4-butynyloxy), a cycloalkyloxy group (preferably having 3 to 20 carbon atoms, such as cyclopropyloxy, cyclopentyloxy, cyclohexyloxy, and 4-methylcyclohexyloxy), an aryloxy group (preferably having 6 to 26 carbon atoms, such as phenoxy, 1-naphthyloxy, 3-methylphenoxy, and 4-methoxyphenoxy), and a heterocyclic oxy group (such as imidazolyloxy, benzimidazolyloxy, thiazolyloxy, benzothiazolyloxy, triazinyloxy, and prynyloxy),

an alkoxycarbonyl group (preferably having 2 to 20 carbon atoms, such as ethoxycarbonyl and 2-ethylhexyloxycarbonyl), a cycloalkoxycarbonyl group (preferably having 4 to 20 carbon atoms, such as cyclopropyloxycarbonyl, cyclopentyloxycarbonyl, and cyclohexyloxycarbonyl), an aryloxycarbonyl group (preferably having 6 to 20 carbon atoms, such as phenyloxycarbonyl and naphthyloxycarbonyl), an amino group (preferably having 0 to 20 carbon atoms, and including an alkylamino group, an alkenylamino group, an alkynylamino group, a cycloalkylamino group, a cycloalkenylamino group, an arylamino group, or a heterocyclic amino group, such as unsubstituted amino (—NH₂), N,N-dimethylamino, N,N-diethylamino, N-ethylamino, N-allylamino, N-(2-propynyl)amino, N-cyclohexylamino, N-cyclohexenylamino, anilino, pyridylamino, imidazolylamino, benzimidazolylamino, thiazolylamino, benzothiazolylamino, and triazinylamino), a sulfamoyl group (preferably having 0 to 20 carbon atoms, preferably an alkyl, cycloalkyl, or aryl sulfamoyl group, such as N,N-dimethylsulfamoyl, N-cyclohexylsulfamoyl, and N-phenylsulfamoyl), an acyl group (preferably having 1 to 20 carbon atoms, such as acetyl, cyclohexylcarbonyl, and benzoyl), an acyloxy group (preferably having 1 to 20 carbon atoms, such as acetyloxy, cyclohexylcarbonyloxy, and benzoyloxy), and a carbamoyl group (preferably having 1 to 20 carbon atoms, preferably an alkyl, cycloalkyl, or aryl carbamoyl group, such as N,N-dimethylcarbamoyl, N-cyclohexylcarbamoyl, and N-phenyl carbamoyl),

an acylamino group (preferably an acylamino group having 1 to 20 carbon atoms, such as acetylamino, cyclohexylcarbonylamino, benzoylamino, and 2-pyrrolidinone-1-yl), a sulfonamide group (preferably having 0 to 20 carbon atoms, preferably an alkyl, cycloalkyl, or aryl sulfonamide group, such as methanesulfonamide, benzenesulfonamide, N-methylmethanesulfonamide, N-cyclohexylsulfonamide, and N-ethylbenzenesulfonamide), an alkylthio group (preferably having 1 to 20 carbon atoms, such as methylthio, ethylthio, isopropylthio, and benzylthio), a cycloalkylthio group (preferably having 3 to 20 carbon atoms, such as cyclopropylthio, cyclopentylthio, cyclohexylthio, and 4-methylcyclohexylthio), an arylthio group (preferably having 6 to 26 carbon atoms, such as phenylthio, 1-naphthylthio, 3-methylphenylthio, and 4-methoxyphenylthio), an alkyl, cycloalkyl, or arylsulfonyl group (preferably having 1 to 20 carbon atoms, such as methyl sulfonyl, ethyl sulfonyl, cyclohexyl sulfonyl, and benzene sulfonyl),

a silyl group (preferably having 1 to 20 carbon atoms, preferably a silyl group substituted with an alkyl, aryl, alkoxy, or aryloxy, such as triethylsilyl, triphenylsilyl, diethylbenzylsilyl, and dimethylphenylsilyl), a silyloxy group (preferably having 1 to 20 carbon atoms, preferably a silyloxy group substituted with an alkyl, aryl, alkoxy, or aryloxy, such as triethylsilyloxy, triphenylsilyloxy, diethylbenzylsilyloxy, and dimethylphenylsilyloxy), a hydroxyl group, a cyano group, a nitro group, a halogen atom (such as a fluorine atom, a chlorine atom, a bromine atom, and an iodine atom), a carboxyl group, a sulfo group, a phosphonyl group, a phosphoryl group, and a boric acid group, more preferably an alkyl group, an alkenyl group, a cycloalkyl group, an aryl group, a heterocyclic group, an alkoxy group, a cycloalkoxy group, an aryloxy group, an alkoxycarbonyl group, a cycloalkoxycarbonyl group, the amino group, an acylamino group, a cyano group, or a halogen atom, and particularly preferably an alkyl group, an alkenyl group, a heterocyclic group, an alkoxy group, an alkoxycarbonyl group, an amino group, an acylamino group, or a cyano group.

Unless otherwise specified, the substituent selected from the substituent group T also includes a group obtained by combining a plurality of the groups described above. For example, in a case where a compound, a substituent, or the like contains an alkyl group, an alkenyl group, or the like, these may be substituted or unsubstituted. In addition, in a case where a compound, a substituent, or the like contains an aryl group, a heterocyclic group, or the like, these may have a monocyclic or condensed ring and may be substituted or unsubstituted.

Specific examples of the compound represented by General Formula (1) will be shown below, but the present invention is not limited thereto.

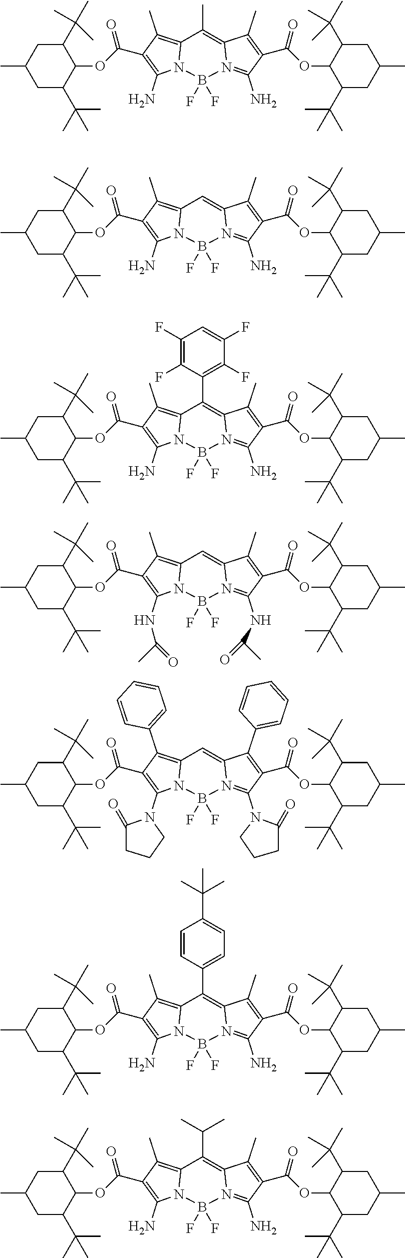

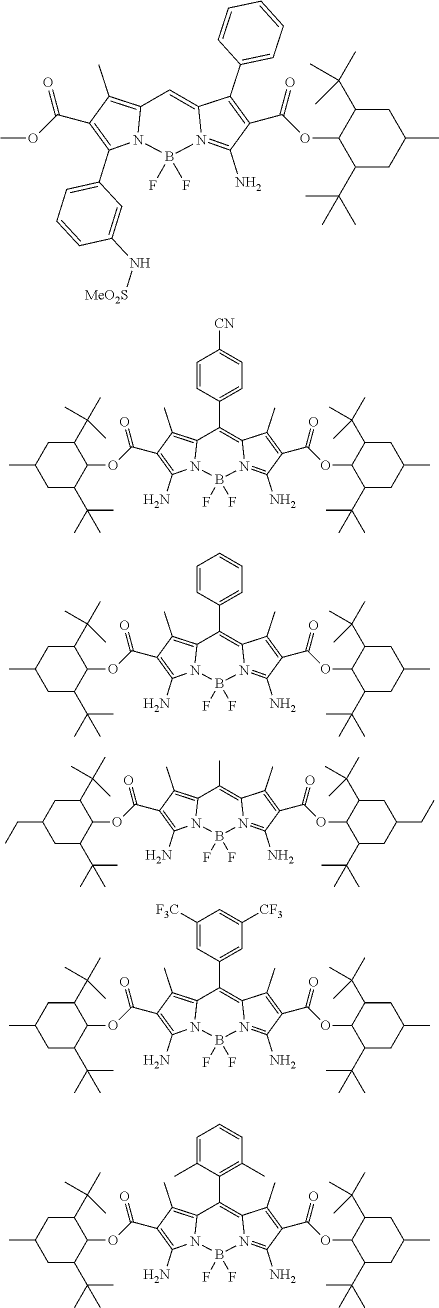

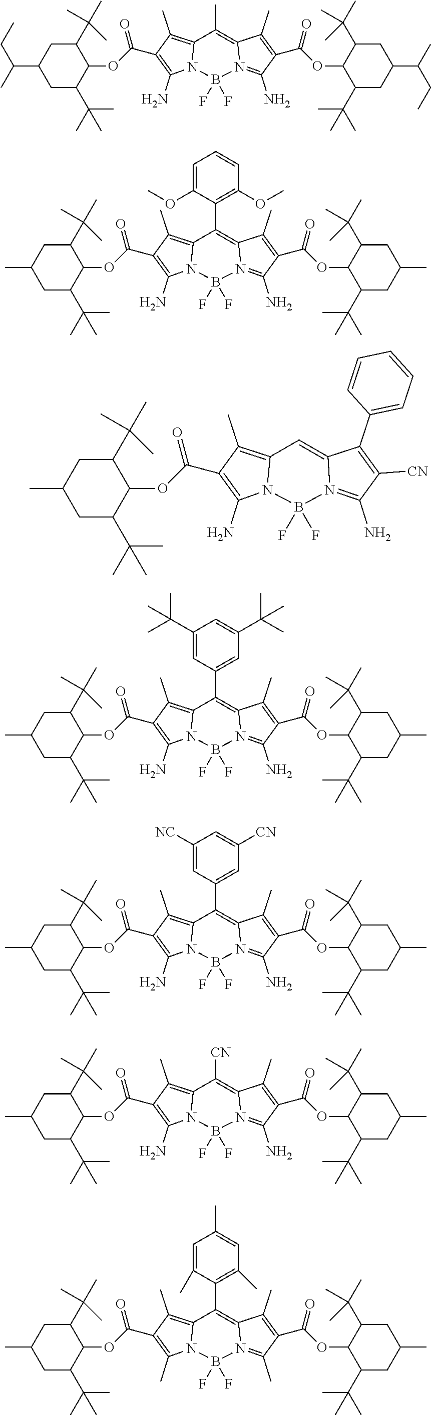

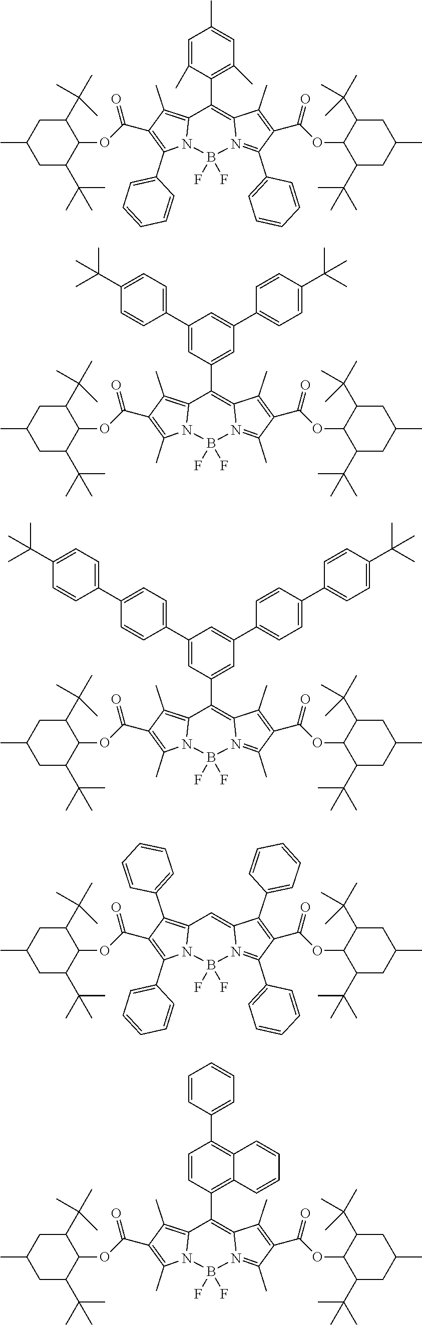

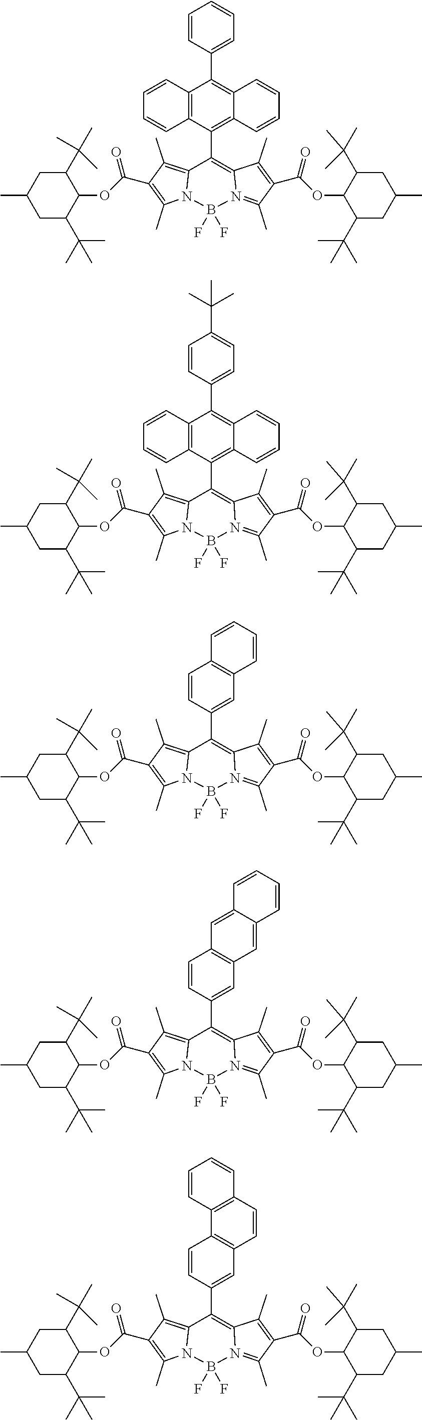

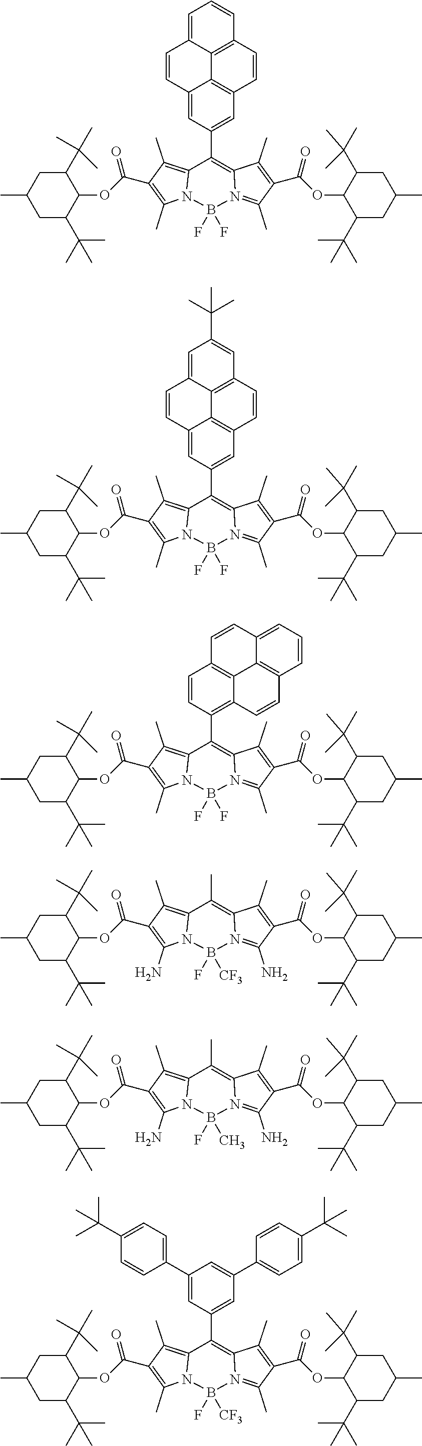

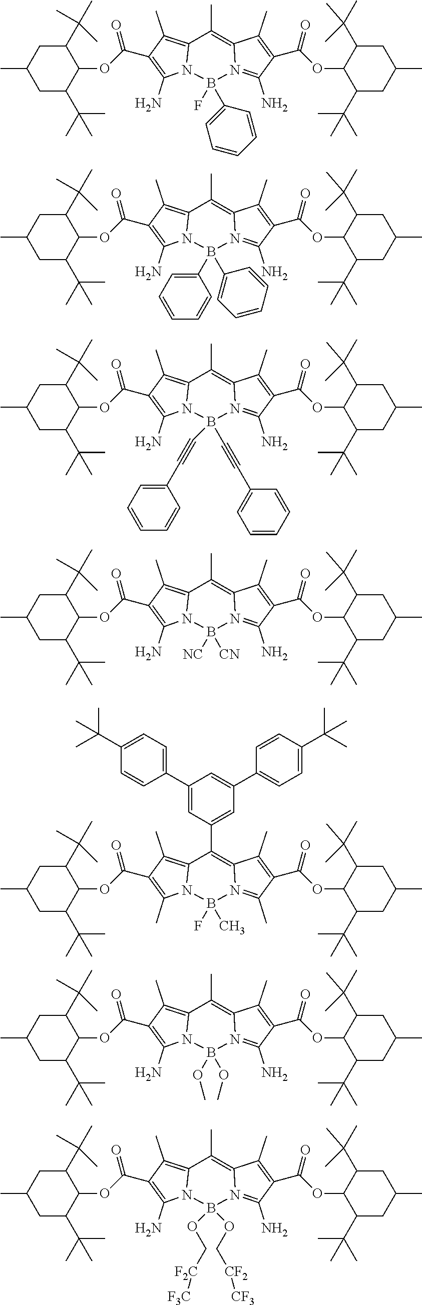

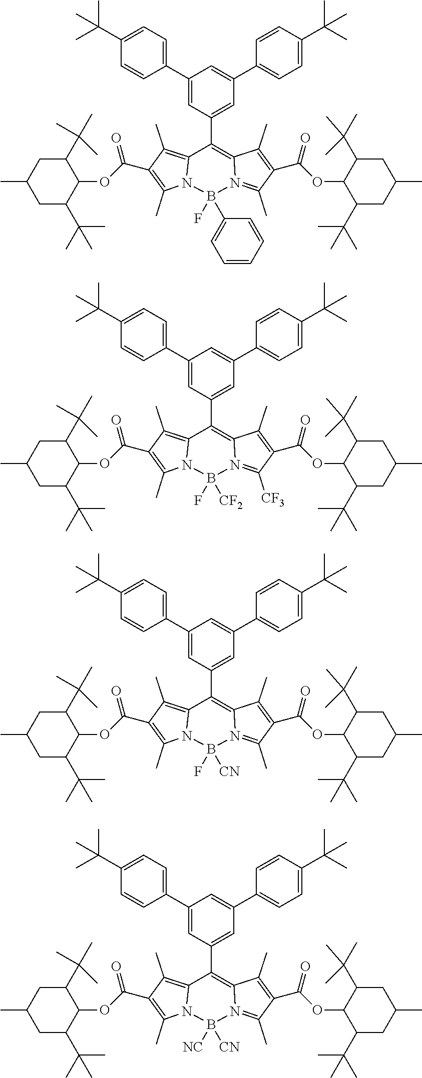

In the material for wavelength conversion according to the embodiment of the present invention, the content of the compound represented by General Formula (1), that is, the content of the compound represented by General Formula (1) per 1 g of solid contents in the material for wavelength conversion according to the embodiment of the present invention is not particularly limited, and is appropriately determined according to the molar absorption coefficient of the compound and the required characteristics (quantum yield, light fastness, moist heat resistance, and the like). For example, the content is preferably 0.01 to 50 μmol/g, more preferably 0.05 to 10 μmol/g, even more preferably 0.1 to 1.0 μmol/g, and most preferably 0.1 to 0.5 μmol/g.

In the material for wavelength conversion according to the embodiment of the present invention, the content of the compound represented by General Formula (1) is not particularly limited as long as the content satisfies the above-described content per 1 g of solid contents. The content is, for example, preferably 0.0005 to 5 parts by mass, more preferably 0.0025 to 1 part by mass, and even more preferably 0.005 to 0.1 parts by mass with respect to 100 parts by mass of a resin to be described later.

As the compound represented by General Formula (1) contained in the material for wavelength conversion according to the embodiment of the present invention, one kind or two or more kinds may be contained. In a case where the material for wavelength conversion according to the embodiment of the present invention contains two or more kinds of compounds represented by General Formula (1), the above content is a total content of the two or more kinds of compounds.

The compound represented by General Formula (1) can be synthesized with reference to a usual synthesis method or a known synthesis method such as the synthesis method described in WO2016/190283A or JP2012-77153A. In addition, the compound can be synthesized according to the synthesis methods of compounds (1-1), (1-2), and (2-1) to be described in Examples to be described later.

### Resin

The material for wavelength conversion according to the embodiment of the present invention may contain a resin. In particular, in a case where a wavelength conversion member to be described later is formed, the material for wavelength conversion usually contains a resin as a binder (also referred to as binder resin). In addition, in a case where luminescent latex particles to be described later are formed, the material for wavelength conversion can contain resin particles.

In the present invention, as the binder resin, it is possible to use a thermoplastic polymer compound, a thermosetting or photocurable polymer compound, or a mixture of the compounds. In the present invention, in a case where the polymer compound is a thermosetting or photocurable polymer compound, the “polymer compound” also includes a compound (monomer) or a polymerization precursor forming the polymer compound.

In a case where the material for wavelength conversion according to the embodiment of the present invention takes a form other than particles (non-particle form), the binder resin is not used in the form of particles.

The binder resin used in the present invention is preferably transparent or semitransparent (having a transmittance equal to or higher than 50% for visible rays (wavelength: 300 to 830 nm)).

Examples of such a binder resin include a (meth)acrylic resin, polyvinyl cinnamate, polycarbonate, polyimide, polyamide imide, polyester imide, polyether imide, polyether ketone, polyether ether ketone, polyether sulfone, polysulfone, polyparaxylene, polyester, polyvinyl acetal, polyvinyl chloride, polyvinyl acetate, polyamide, polystyrene, polyurethane, polyvinyl alcohol, cellulose acylate, a fluorinated resin, a silicone resin, an epoxy silicone resin, a phenol resin, an alkyd resin, an epoxy resin, a maleic acid resin, a melamine resin, a urea resin, aromatic sulfonamide, a benzoguanamine resin, a silicone elastomer, aliphatic polyolefin (such as polyethylene and polypropylene), and a cyclic olefin copolymer.

As the binder resin, polystyrene, a (meth)acrylic resin, cellulose acylate, a silicone resin, or a mixture of two or more kinds thereof is preferable.

The mass average molecular weight of the binder resin is not particularly limited, and is, for example, preferably 1,000 to 100,000.

As the binder resin contained in the material for wavelength conversion according to the embodiment of the present invention, one kind or two or more kinds may be contained.

The content of the binder resin in the solid content of the material for wavelength conversion is not particularly limited. For example, the content can be equal to or greater than 50 mass %, and is preferably equal to or greater than 90 mass %.

### Solvent

The material for wavelength conversion according to the embodiment of the present invention can also be a liquid material containing a solvent. The solvent to be used is not particularly limited, and examples thereof include solvents described in a method of preparing the material for wavelength conversion to be described later.

The content of the solvent in the material for wavelength conversion is not particularly limited. For example, the content can be equal to or greater than 50 mass%, and is preferably equal to or greater than 70 mass%.

### Additives

The material for wavelength conversion according to the embodiment of the present invention may contain various additives which are usually used in the material for wavelength conversion. Examples of such additives include photoluminescent phosphors other than the compound represented by General Formula (1) specified in the present invention, inorganic phosphors, colorants for color tone correction, processing, oxidation, and heat stabilizers (such as antioxidants and phosphorus-based processing stabilizers), light fastness stabilizers (such as ultraviolet absorbers), silane coupling agents, organic acids, matting agents, radical scavengers, deterioration inhibitors, fillers (such as silica, glass fibers, and glass beads), plasticizers, lubricants, flame retardants (such as organic halogen compounds), flame retardant aids, antistatic agents, chargeability imparting agents, impact resistance enhancers, discoloration inhibitors, release agents (such as higher fatty acid esters of monohydric or polyhydric alcohols), fluidity enhancers, and reactive or non-reactive diluents.

The material for wavelength conversion according to the embodiment of the present invention preferably does not contain a fluorescence absorbing substance such as an infrared absorbing compound in order to effectively exhibit the wavelength conversion function.

The photoluminescent phosphors other than the compound represented by General Formula (1) specified in the present invention are not particularly limited, and examples thereof include known photoluminescent phosphors (colorants). Specific examples of the various additives include “other components” described in WO2016/190283A and those described in JP2011-241160A. The descriptions thereof are preferably incorporated into the present specification. In addition, the content of the additives is not particularly limited, and is appropriately determined within a range not impairing the objects of the present invention.

Any one of the compound represented by General Formula (1) contained in the material for wavelength conversion according to the embodiment of the present invention or the compound represented by General Formula (1A) of the present invention (hereinafter, also referred to as “compound of (1) or (1A) specified in the present invention”) has excellent solubility in a solvent or a raw material monomer constituting the resin, and also has a large molar absorption coefficient.

The reason for this is not clear, but is thought as follows. That is, at least one specific partial structure represented by Formula (A) in the compound of (1) or (1A) specified in the present invention is a bulky structure having high hydrophobicity. Therefore, it is thought that since the affinity with a medium is increased due to the specific partial structure represented by Formula (A) and the intermolecular interaction of the compound of (1) or (1A) specified in the present invention is suppressed by steric hindrance, the solubility can be effectively increased. In addition, it is thought that in the compound of (1) or (1A) specified in the present invention, since the expansion of the highest occupied molecular orbital (HOMO) and the lowest unoccupied molecular orbital (LUMO) is large and the overlap between the HOMO and the LUMO is large, the molar absorption coefficient can be further increased.

In addition, the compound of (1) or (1A) specified in the present invention can exhibit an excellent quantum yield of a level which is as excellent as that of a dipyrromethene boron complex compound used for a material for wavelength conversion according to the related art, which will be shown in Examples to be described later, and can thus exhibit excellent emission efficiency in combination with an improvement of the molar absorption coefficient. That is, the ratio of the intensity of outgoing rays to the intensity of incoming rays can be further increased.

As described above, the compound of (1) or (1A) specified in the present invention, which has excellent solubility, is less likely to cause deterioration of performance due to aggregation or deterioration of manufacturing suitability due to precipitation in the preparation of the material for wavelength conversion, and can thus be allowed to uniformly exist at a high concentration in the material for wavelength conversion. In addition, the compound has a large molar absorption coefficient and an excellent quantum yield. As a result, desired high luminance can be realized in the material for wavelength conversion formed of the compound. The same is true of a wavelength conversion portion and a light emitting device according to the embodiment of the present invention.

In addition, with the spread of light emitting devices such as display devices and lighting devices, fluorescent compounds and materials for wavelength conversion containing the fluorescent compounds used in these devices are required to have not only the above-described excellent solubility and excellent emission efficiency but also high light fastness, high durability against moisture and heat (moist heat resistance), and the like.

The compound of (1) or (1A) specified in the present invention and the material for wavelength conversion according to the embodiment of the present invention can exhibit excellent light fastness and moist heat resistance in addition to excellent solubility and excellent emission efficiency. Details of the reason for this are not clear, but are thought as follows.

It is thought that due to the partial structure represented by Formula (A), the compound of (1) or (1A) specified in the present invention can obtain actions of preventing the approach of a reactive substance due to steric hindrance, preventing the approach of water (reactive substance) due to hydrophobization, and preventing hue change due to the suppression of association of the compound of (1) or (1A) specified in the present invention, and can thus exhibit excellent light fastness and moist heat resistance due to the actions.

### Method of Preparing Material for Wavelength Conversion

The method of preparing the material for wavelength conversion according to the embodiment of the present invention is not particularly limited, and examples thereof include the following methods A to C.

Method A: a method including a step of dissolving or suspending the compound represented by General Formula (1) specified in the present invention, an optional binder resin, and optional additives in a solvent as needed.

In the method A, the solution obtained by the above step can be dried.

Method B: a method including a step of curing a mixture including the compound represented by General Formula (1) specified in the present invention, an optional monomer and/or polymerization precursor forming the binder resin, and optional additives.

Examples thereof include a method in which the compound represented by General Formula (1) specified in the present invention and optional additives are mixed with (dispersed in) a monomer or a polymerization precursor of a thermosetting or photocurable polymer, and then the monomer or the polymerization precursor are polymerized. A method in which the compound represented by General Formula (1) specified in the present invention and optional additives are mixed with (dissolved or suspended in) a solution of a monomer or a polymerization precursor, a solvent is then removed, and the monomer or the polymerization precursor is polymerized is also included.

Method C: a method including a step of melting a mixture of the compound represented by General Formula (1) specified in the present invention, an optional binder resin, and optional additives.

Examples thereof include a method in which the compound represented by General Formula (1) specified in the present invention and optional additives are dispersed in a binder resin, and then the dispersion is melted.

In a case where a solvent is not used in the methods A to C and in a case where the solution is dried, the material for wavelength conversion according to the embodiment of the present invention can be prepared as a solid mixture.

The method of mixing (dissolving, suspending, or dispersing) the compound represented by General Formula (1) specified in the present invention with a solvent or a binder resin is not particularly limited. It is possible to use a stirring method, melt blending, a method of mixing the compound with a binder resin powder, and the like. As the melt blending method, known methods can be applied without particular limitation, and the melt blending conditions can be set as appropriate. For example, as devices used for melt blending or dispersion and melting temperature conditions, for example, the devices and the temperature conditions described in JP2011-241160A can be applied, and the descriptions thereof are preferably incorporated into the present specification.

In a case where a solvent is used, examples of the solvent include various solvents such as a hydrocarbon such as toluene, a ketone compound, a halogenated hydrocarbon such as methylene chloride, an ester compound, an alcohol compound such as methanol, and an ether compound, polar solvents such as N,N-dimethylformamide, N,N-dimethylacetamide, 1-methyl-2-pyrrolidone, 1,3-dimethylimidazolidinone, and dimethyl sulfoxide, and water. One kind of solvent may be used singly, or a plurality of solvents may be used in combination. Specific examples of the solvents include the organic solvents described in JP2011-241160A, and the descriptions of the solvents are preferably incorporated into the present specification.

The method of removing the solvent is not particularly limited. Usually, examples thereof include a method of evaporating and removing the solvent by leaving the solvent at room temperature or by air blowing, a method of evaporating and removing the solvent by heating, a method of evaporating and removing the solvent under reduced pressure (equal to or lower than atmospheric pressure), and a method as a combination of these.

The method of polymerizing the monomer and/or polymerization precursor in the method B is not particularly limited, and may be thermal polymerization or photopolymerization.

The thermal polymerization can be performed in the usual manner. Examples of the thermal polymerization method include a method in which a catalyst is added as needed to a mixture of the above-described monomer and/or polymerization precursor and the compound represented by General Formula (1) specified in the present invention, and then the mixture is heated. Regarding the thermal polymerization method, the thermal polymerization conditions, the catalyst to be used, and the amount of the catalyst to be used, for example, the method described in JP2011-241160A can be referred to, and the descriptions of the publication are preferably incorporated into the present specification.

Photopolymerization can be performed in the usual manner. Examples of the photopolymerization method include a method in which a photopolymerization initiator is added as needed to a mixture of the above-described monomer and/or polymerization precursor and the compound represented by General Formula (1) specified in the present invention, and then the mixture is irradiated with light. Regarding the photopolymerization method, the photopolymerization conditions, the polymerization initiator to be used, and the amount of the polymerization initiator to be used, for example, the method described in JP2011-241160A can be referred to, and the descriptions of the publication are preferably incorporated into the present specification.

In a case where the binder resin is a silicone resin, a polymerization method using an addition curing reaction is preferable. The addition curing reaction of the silicone resin can also be performed in the usual manner. For example, the polymerization is preferably carried out by a hydrosilylation reaction between organosiloxane having a polymerizable reactive group (for example, alkenyl group) and hydrogensiloxane having a hydrogen atom bonded to a silicon atom. The conditions of the hydrosilylation reaction are not particularly limited, and examples thereof include a condition in which the composition is heated to a temperature equal to or higher than room temperature, for example, to 50° C. to 200° C. in the presence of an addition reaction catalyst (such as platinum catalyst) as desired.

### Luminescent Particles

By making the material for wavelength conversion according to the embodiment of the present invention into a particle shape, the material can also be used as luminescent particles. The material of the particles is not particularly limited, and for example, in a case where organic polymer particles such as polystyrene beads are used, the compound represented by General Formula (1) is impregnated into the particles or adsorbed on surfaces of the particles to obtain luminescent particles. Usually, the compound mainly exists in a state of being impregnated into the particles.

In addition, inorganic particles such as silica gel or glass beads can also be used, and in this case, the compound represented by General Formula (1) is adsorbed on surfaces of the particles to obtain luminescent particles.

Specific examples of the material of the particles include a homopolymer obtained by polymerizing a monomer such as styrene, a methacrylic acid, glycidyl (meth)acrylate, butadiene, vinyl chloride, vinyl acetate acrylate, methyl methacrylate, ethyl methacrylate, phenyl methacrylate, or butyl methacrylate, a copolymer obtained by polymerizing two or more kinds of monomers, cellulose, and cellulose derivatives. A latex obtained by uniformly suspending the homopolymer or copolymer may also be used. In addition, examples of the particles include other organic polymer powders, inorganic substance powders, microorganisms, blood cells, cell membrane fragments, liposomes, and microcapsules. The particles are preferably latex particles.

In a case where latex particles are used, specific examples of the material of the latex include polystyrene, a styrene-acrylic acid copolymer, a styrene-methacrylic acid copolymer, a styrene-glycidyl (meth)acrylate copolymer, a styrene-styrene sulfonate copolymer, a methacrylic acid polymer, an acrylic acid polymer, an acrylonitrile-butadiene-styrene copolymer, a vinyl chloride-acrylic acid ester copolymer, and polyvinyl acetate acrylate. As the latex, a copolymer containing at least styrene as a monomer is preferable, and a copolymer of styrene and an acrylic acid or methacrylic acid is particularly preferable. The method of preparing the latex is not particularly limited, and the latex can be prepared by an optional polymerization method. However, in a case where the luminescent particles are used with an antibody labeled thereon, the presence of a surfactant makes it difficult to immobilize the antibody. Therefore, in the preparation of a latex, it is preferable that emulsifier-free emulsion polymerization, that is, emulsion polymerization without using an emulsifier such as a surfactant is used, or a latex is prepared by emulsion polymerization using an emulsifier such as a surfactant, and then the surfactant is removed or reduced by purification. The method for removing or reducing the surfactant is not particularly limited, and a purification method in which a latex is precipitated by centrifugation, and then removing the supernatant is repeated is preferable.

In a case where emulsifier-free emulsion polymerization is used in the preparation of a latex, the average particle diameter can be controlled in a range of 80 to 300 nm by changing the reaction temperature, the monomer composition ratio (for example, ratio of styrene to acrylic acid), and the amount of the polymerization initiator.

In a case where emulsion polymerization using a surfactant (such as sodium dodecyl sulfate) is used in the preparation of a latex, the average particle diameter can be suppressed in a range of 30 to 150 nm by changing the amount of the surfactant, the reaction temperature, the monomer composition ratio (for example, ratio of styrene to acrylic acid), and the amount of the polymerization initiator.

The average particle diameter of the latex particles has the same definition as the average particle diameter of luminescent particles to be described later, and as a measuring method, a method of measuring the average particle diameter of luminescent particles to be described later is applied.

### Luminescent Particles

In a case where the luminescent particles contain the compound represented by General Formula (1), the association of the compound in the latex particles is suppressed due to the partial structure represented by Formula (A) included in the compound represented by General Formula (1). As a result, in a case where the number of moles (compound amount) of the compound represented by General Formula (1) with respect to the latex is increased, the fluorescence intensity corresponding to the compound amount can be obtained, and high luminance can be exhibited.

The incoming rays and the outgoing rays for causing the luminescent particles to emit light have the same definition as the incoming rays and the outgoing rays in the above-described material for wavelength conversion.

The emission maximum wavelength of the luminescent particles can be measured using a commercially available fluorescence spectrophotometer. For example, it can be measured using a fluorescence spectrophotometer RF-5300PC manufactured by Shimadzu Corporation.

The quantum yield of the luminescent particles is a ratio of the number of photons emitted as fluorescence to the number of photons absorbed by the luminescent particles.

The quantum yield of the luminescent particles is preferably equal to or greater than 0.25, more preferably equal to or greater than 0.4, even more preferably equal to or greater than 0.5, still more preferably equal to or greater than 0.6, and particularly preferably equal to or greater than 0.7. The upper limit of the quantum yield is not particularly limited, and is generally equal to or less than 1.0.

The quantum yield of the luminescent particles can be measured using a commercially available quantum yield measuring device, and for example, can be measured using an absolute PL quantum yield spectrometer C9920-02 manufactured by Hamamatsu Photonics K.K.

### Method of Measuring Average Particle Diameter (Average Particle Diameter) of Luminescent Particles

The average particle diameter of the luminescent particles varies depending on the material of the particles, the concentration range for measuring the test substance, the measuring device, and the like; however, it is preferably in a range of 0.001 to 10 μm (more preferably 0.01 to 1 μm), more preferably in a range of 30 to 500 nm, even more preferably in a range of 50 to 300 nm, particularly preferably in a range of 80 to 200 nm, and most preferably in a range of 100 to 150 nm. The average particle diameter of the luminescent particles which can be used in the present invention can be measured by a commercially available particle size distribution meter or the like. As a method of measuring the particle size distribution, optical microscopy, confocal laser microscopy, electron microscopy, atomic force microscopy, a static light scattering method, a laser diffraction method, a dynamic light scattering method, a centrifugal sedimentation method, an electric pulse measurement method, a chromatography method, an ultrasonic attenuation method, and the like are known, and devices corresponding to the respective principles are commercially available. Among these measuring methods, a dynamic light scattering method is preferably used to measure the average particle diameter of the luminescent particles from the viewpoint of the particle diameter range and ease of the measurement. Examples of commercially available measuring devices using dynamic light scattering include NANOTRAC UPA (Nikkiso Co., Ltd.), a dynamic light scattering particle size distribution analyzer LB-550 (HORIBA, Ltd.), and a fiber-optics particle diameter analyzer FPAR-1000 (Otsuka Electronics Co., Ltd.). In the present invention, the average particle diameter is obtained as a median diameter (d=50) measured at 25° C. under the conditions of a viscosity of 0.8872 CP and a refractive index of water of 1.330.

### Method of Manufacturing Luminescent Particles

The method of manufacturing the luminescent particles is not particularly limited, and it is possible to manufacture the particles by mixing at least one kind of compound represented by General Formula (1) and particles. For example, by adding the compound represented by General Formula (1) to particles such as latex particles, the luminescent particles can be prepared. More specifically, the luminescent particles can be manufactured by adding a solution containing the compound represented by General Formula (1) to a dispersion of particles containing water and any one or more kinds of water-soluble organic solvents (tetrahydrofuran, methanol, and the like) and stirring the mixture.

### Dispersion

According to the present invention, a dispersion containing the above-described luminescent particles is provided.

The dispersion can be manufactured by dispersing the luminescent particles in a dispersion medium. Examples of the dispersion medium include water, an organic solvent, and mixtures of water and an organic solvent. An alcohol such as methanol, ethanol, or isopropanol, an ether-based solvent such as tetrahydrofuran, or the like can be used as the organic solvent.

The concentration of solid contents of the luminescent particles in the dispersion is not particularly limited; however, it is generally 0.1 to 20 mass %, preferably 0.5 to 10 mass%, and more preferably 1 to 5 mass %.

### Use of Luminescent Particles

In a case where the number of moles (compound amount) of the compound represented by General Formula (1) with respect to the latex is increased, the fluorescence intensity corresponding to the compound amount can be obtained, and the luminescent particles can exhibit high luminance. Therefore, the luminescent particles can be suitably used for a fluorescence detection method or the like, and can be used in, for example, a fluorescence detection method for quantifying proteins, enzymes, inorganic compounds or the like.

### Light Emitting Device

A light emitting device according to the embodiment of the present invention has a wavelength conversion portion formed of the material for wavelength conversion according to the embodiment of the present invention and a light source, and emits light of an intended wavelength. In the present invention, a unit consisting of a wavelength conversion portion and a light source is called wavelength conversion unit in some cases. The wavelength conversion portion has a function of absorbing light (incoming rays) emitted (radiated) from the light source, and emitting (wavelength conversion) light (outgoing rays) of a specific wavelength (generally, a wavelength longer than the wavelength of the incoming rays) different from the wavelength of the incoming rays. In this case, the wavelength conversion portion totally or partially absorbs the light from the light source and radiates light of a specific wavelength. For example, in a case where the entirety of the light emitting device according to the embodiment of the present invention emits white light (a white LED, white lighting, or the like), the light emitting device can emit red light or green light by partially absorbing blue light from the light source, and the entirety of the device can emit white light with the blue light from the light source. In this case, the wavelength conversion portion functions to convert light into red light or green light.

As the structure of the light emitting device according to the embodiment of the present invention, a structure which has been known can be applied without particular limitation. Details thereof will be described later.

In the light emitting device according to the embodiment of the present invention, the way the wavelength conversion portion and the light source are arranged is not particularly limited. The wavelength conversion portion and the light source may be arranged close to or in contact with each other, or may be arranged in separate positions or in a state where another member is interposed therebetween. As described above, since the material for wavelength conversion according to the embodiment of the present invention and the wavelength conversion portion can exhibit excellent light fastness and moist heat resistance, the wavelength conversion portion and the light source can be arranged close to or in contact with each other. Even in a case where such arrangement is employed, incoming rays can be subjected to wavelength conversion with excellent wavelength conversion efficiency and emitted as outgoing rays, and the light can be emitted for a long period of time with a high quantum yield.

The light emitting device according to the embodiment of the present invention can be used in a white LED or as a white LED. In this case, the light emitting device still exhibits excellent wavelength conversion efficiency and excellent light fastness and moist heat resistance.

### Wavelength Conversion Portion

The shape, dimensions, and the like of the wavelength conversion portion of the present invention are not particularly limited as long as the wavelength conversion portion is formed of the material for wavelength conversion according to the embodiment of the present invention, and are appropriately set according to the use and the like. For example, the wavelength conversion portion used in the light emitting device according to the embodiment of the present invention may be the material for wavelength conversion according to the embodiment of the present invention or a molded article. In a case where the wavelength conversion portion is the material for wavelength conversion according to the embodiment of the present invention, the wavelength conversion portion is usually formed by applying (coating or arranging) the material for wavelength conversion according to the embodiment of the present invention to a surface on which the wavelength conversion portion is to be installed. In a case where the wavelength conversion portion is a molded article, the shape thereof is not particularly limited. For example, the molded article may have a film shape, a plate shape (such as a sheet shape, a film shape, or a disk shape), a lens shape, a fiber shape, an optical waveguide shape, or the like.

In one preferable aspect, the wavelength conversion portion has a plate shape. In this case, the wavelength conversion portion (also referred to as wavelength conversion filter) may be formed as a wavelength conversion layer formed of the material for wavelength conversion according to the embodiment of the present invention. The thickness of the wavelength conversion layer is not particularly limited, and is, for example, preferably 10 to 3,000 μm, and more preferably 30 to 2,000 μm.

The wavelength conversion portion may be a laminate (wavelength conversion member) provided on a substrate or the like.

Examples of the substrate include a glass substrate and a resin substrate. Examples of the glass substrate include substrates made of various types of glass such as soda-lime glass, barium-strontium-containing glass, lead glass, aluminosilicate glass, borosilicate glass, barium-borosilicate glass, and quartz. Examples of the resin substrate include substrates made of various resins such as polycarbonate, an acrylic resin, polyethylene terephthalate, polyether sulfide, and polysulfone.

The wavelength conversion portion may have a constituent member other than the substrate. Such a constituent member is not particularly limited as long as it is usually used for wavelength conversion members, and examples thereof include a protective film (film).

The wavelength conversion portion can subject incoming rays to wavelength conversion with excellent wavelength conversion efficiency and emit the rays as outgoing rays, and can also emit the light for a long period of time with a high quantum yield.

The quantum yield of the wavelength conversion portion is preferably equal to or greater than 0.7. The upper limit of the quantum yield is not particularly limited, and is generally equal to or less than 1.0. In the present invention, the quantum yield can be measured using a commercially available quantum yield measuring device. For example, the quantum yield of the wavelength conversion portion (thickness: 60 μm) can be measured using an absolute photoluminescence (PL) quantum yield measuring device: C9920-02 (manufactured by Hamamatsu Photonics K.K.).

In a case where the wavelength conversion portion is a molded article, the wavelength conversion portion is prepared by molding the material for wavelength conversion according to the embodiment of the present invention into a predetermined shape.

The molding method is not particularly limited, and examples thereof include a molding method such as injection molding performed in a hot melt state and a film forming method performed after the material for wavelength conversion according to the embodiment of the present invention is melted. The film forming method is not particularly limited, and examples thereof include a spin coating method, a roll coating method, a bar coating method, a Langmuir-Blodgett method, a casting method, a dipping method, a screen printing method, a Bubble jet (registered trademark) method, an ink jet method, a vapor deposition method, and an electric field method.

In a case where the binder resin is a thermosetting or photocurable resin, it is also possible to apply the method described above in which a mold is filled with a mixture of a monomer and/or a polymerization precursor of the binder resin, the compound represented by General Formula (1) specified in the present invention, and the like, or the mixture is formed into a film by the above-described film forming method, and then the mixture is polymerized by light or heat.

### Light Source

The light source used in the light emitting device according to the embodiment of the present invention is not particularly limited as long as it emits light of an emission wavelength (wavelength light) capable of exciting at least the compound represented by General Formula (1) specified in the present invention and preferably all the fluorescent compounds contained in the wavelength conversion portion. Examples of such a light source include incandescent lamps, metal halide lamps, high intensity discharge (HID) lamps, xenon lamps, sodium lamps, mercury lamps, fluorescent lamps, cold cathode fluorescent lamps, cathode luminescence, low-speed electronic beam tubes, light emitting diodes [for example, GaP (red and green), GaPₓAs₍₁₋ₓ₎ (red, orange, and yellow: 0<x<1), AlₓGa₍₁₋ₓ₎As (red: 0<x<1), GaAs (red), SiC (blue), GaN (blue), ZnS, and ZnSe], electroluminescence (such as an inorganic EL or an organic EL using a ZnS matrix and an emission center), lasers (such as a He—Ne laser, a CO₂ laser, an Ar, Kr, He—Cd laser, an excimer laser, a gas laser such as a nitrogen laser, a ruby laser, an yttrium-aluminum-garnet (YAG) laser, a solid state laser such as a glass laser, a dye laser, and a semiconductor laser), and sunlight.

The light source is preferably a light emitting diode, electroluminescence, or a semiconductor laser, and more preferably a light emitting diode.

As the light emitting diode, a semiconductor light emitting element is preferable which has a light emitting layer which can emit light of an emission wavelength capable of exciting at least the compound represented by General Formula (1) specified in the present invention. Examples of such a semiconductor light emitting element include semiconductor light emitting elements having a light emitting layer containing the semiconductor described above. As a semiconductor other than the above-described semiconductors, a nitride semiconductor (InₓAl_{y}Ga_{(1-x-y)}, 0≤X, 0≤Y, X+Y≤1) is preferable which can emit light of a short wavelength capable of efficiently exciting the compound represented by General Formula (1) specified in the present invention. More preferably, the light emitting layer does not contain the compound represented by General Formula (1) specified in the present invention. The semiconductor contained in the light emitting layer is preferably an inorganic semiconductor. Examples of the structure of the semiconductor include a homo-structure having a metal-insulator-silicon (MIS) junction, a PIN junction, a pn junction, or the like, a hetero structure, and a double heterostructure. Various emission wavelengths can be selected according to the material of the light emitting layer or the degree of mixing of crystals in the light emitting layer. Furthermore, it is possible to adopt a single quantum well structure or a multiple quantum well structure obtained by forming the light emitting layer as a thin film that brings about a quantum effect.

In a case where the light emitting device according to the embodiment of the present invention is caused to emit white light as will be described later, the emission wavelength (excitation wavelength) of the light source is preferably 350 to 480 nm in consideration of the complementary color relationship with the emission wavelength from the compound represented by General Formula (1) specified in the present invention or the deterioration of the binder resin. In order to further improve the excitation and emission efficiency of the light source and the compound represented by General Formula (1) specified in the present invention, the emission wavelength is more preferably 380 to 450 nm. In general, the light emitting diode is disposed on a substrate such as copper foil having a patterned metal. Herein, examples of the material of the substrate include an organic or inorganic compound (such as glass and ceramics) having insulating properties. As the organic compound, various polymer materials (such as an epoxy resin and an acrylic resin) can be used. The shape of the substrate is not particularly limited, and various shapes such as a plate shape, a cup shape, and a porous plate shape can be selected.

The semiconductor laser is not particularly limited, and preferably has the following mechanism. That is, a pn junction is formed in a semiconductor, a forward bias is applied thereto, and minority carriers at a high energy level are injected into the semiconductor such that the electrons flowing into the p region are recombined with holes and the holes flowing into the n region are recombined with electrons. Accordingly, electrons are transited to a low energy level from a high energy level, and photons equivalent to the energy difference are released. This is an example of the mechanism of the semiconductor laser described above.

Examples of the material of the semiconductor laser include group IV elements such as germanium and silicon and direct transition type group III-V and group II-VI compounds such as GaAs and InP that do not result in lattice vibration. Furthermore, not only binary materials but also multi-element materials such as ternary, quaternary, and quinary materials may be used as these materials. In addition, the semiconductor laser may have a laminated structure such as a double heterostructure provided with a clad layer, or may be constituted with a lower clad, an active layer, and an upper clad. Moreover, a multiple quantum well structure may also be applied.

The light emitting device according to the embodiment of the present invention may include a color filter as desired. In a case where the light emitting device has a color filter, the color purity can be adjusted. The color filter is not particularly limited as long as it is a commonly used color filter. Examples of pigments used for the color filter include various pigments such as perylene pigments, lake pigments, azo pigments, quinacridone pigments, anthraquinone pigments, anthracene pigments, isoindoline pigments, isoindolinone pigments, phthalocyanine pigments, basic triphenylmethane dyes, indanthrone pigments, indophenol pigments, cyanine pigments, and dioxazine pigments, a pigment mixture of two or more kinds of pigments among these, and a mixture of the pigment or pigment mixture described above and a binder resin (solid-state mixture in which the pigment or the pigment mixture and the binder resin are dissolved or dispersed).

In the light emitting device according to the embodiment of the present invention, the compound represented by General Formula (1) specified in the present invention can convert incoming rays from the light source and preferably incoming rays in the above-described wavelength region into outgoing rays of a predetermined wavelength with excellent conversion efficiency to emit the outgoing rays, and emit the outgoing rays for a long period of time.

The light emitted by the entirety of the light emitting device according to the embodiment of the present invention may be only the light subjected to wavelength conversion by the compound represented by General Formula (1) specified in the present invention or the wavelength conversion portion, or may be mixed light of the above light and the wavelength light from the light source.

### Configuration of Light Emitting Device

The configuration of the light emitting device according to the embodiment of the present invention is not particularly limited, and examples thereof include the following configurations.

Specific examples of the configuration include light source/wavelength conversion portion, light source/light transmitting substrate/wavelength conversion portion, light source/wavelength conversion portion/light transmitting substrate, light source/light transmitting substrate/wavelength conversion portion/light transmitting substrate, light source/wavelength conversion portion/color filter, light source/light transmitting substrate/wavelength conversion portion/color filter, light source/wavelength conversion portion/light transmitting substrate/color filter, light source/light transmitting substrate/wavelength conversion portion/light transmitting substrate/color filter, light source/light transmitting substrate/wavelength conversion portion/color filter/light transmitting substrate, and light source/wavelength conversion portion/color filter/light transmitting substrate. In each configuration, the wavelength conversion portion is formed of the material for wavelength conversion according to the embodiment of the present invention. In addition, the light emitting device may have another wavelength conversion portion performing wavelength conversion to generate light different from the light converted by the wavelength conversion portion. In this case, the arrangement relationship between the wavelength conversion portion formed of the material for wavelength conversion according to the embodiment of the present invention and another wavelength conversion portion is not particularly limited. For example, the wavelength conversion portions may be arranged in a line. In each configuration, the respective constituents are arranged in contact with or separated from each other.

The light transmitting substrate refers to a substrate which can transmit 50% or more of visible light. Specifically, the light transmitting substrate has the same definition as the substrate that the wavelength conversion portion may have. The color filter has the same definition as the color filter that the wavelength conversion portion may have. The shapes of the light transmitting substrate and the color filter are not particularly limited, and the light transmitting substrate and the color filter may have a plate shape or a lens shape.

The light emitting device according to the embodiment of the present invention can be used for various purposes. For example, the light emitting device can be preferably used in display devices such as various displays, lighting devices, and the like.

The display devices are not particularly limited, and examples thereof include various (liquid crystal) displays, liquid crystal backlights, liquid crystal front lights, liquid crystal display devices such as field-sequential liquid crystal displays, traffic signals, and traffic display devices. The lighting devices are not particularly limited, and examples thereof include general lighting devices (instruments), local lighting devices, and lighting devices for interior decoration.

The light emitting device according to the embodiment of the present invention can be prepared by known methods. For example, the light emitting device can be prepared by sequentially laminating the constituents used in the above-described configuration, or by bonding the constituents to each other. The lamination order of the constituents is no particular limited.

### EXAMPLES

Hereinafter, the present invention will be described in more detail based on Examples, but is not limited thereto.

Compounds (1-1), (1-2), and (2-1) and comparative compounds (1) to (3) used in Examples and Comparative examples will be shown below.

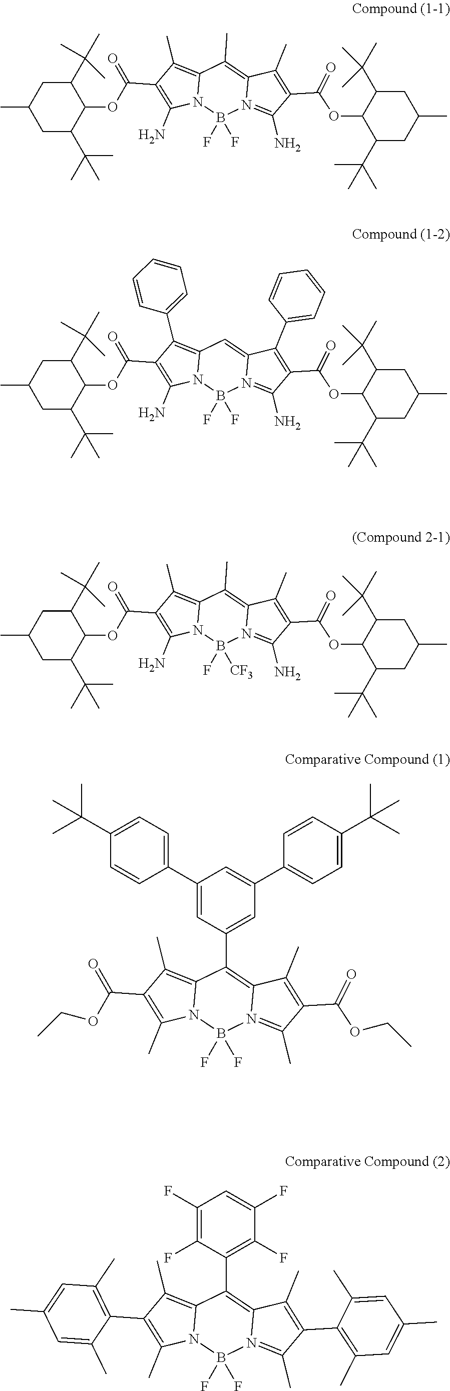

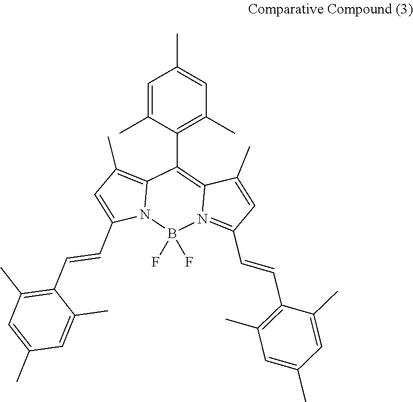

The comparative compound (1) is the compound G-32 described in paragraph “0223” of WO2016/190283A.

The comparative compound (2) is the compound (5-A) described in JP2018-146659A.

The comparative compound (3) is the compound (2) described in WO2018/117073A.

Hereinafter, the method of synthesizing the compounds (1-1), (1-2), and (2-1) used in Examples will be specifically described, but the starting material, the intermediate, and the synthesis route are not limited thereto.

In the present invention, room temperature means 25° C.

Abbreviations used in the synthesis of each compound shown below represent the following compounds.

DIPEA: N,N-diisopropylethylamine

DBU: 1,8-diazabicyclo[5.4.0]undec-7-ene

TMSOTf: trimethylsilyl trifluoromethanesulfonate

Unless otherwise specified, SNAP KP-Sil Cartridge (manufactured by Biotage Ltd.) or a high flash column W001, W002, W003, W004, or W005 (manufactured by YAMAZEN CORPORATION) was used as a carrier in silica gel column chromatography.

The MS spectrum was measured using ACQUITY SQD LC/MS System [manufactured by Waters Corporation, ionization method: electrospray Ionization (ESI)] or LCMS-2010EV [manufactured by Shimadzu Corporation, ionization method: an ionization method simultaneously performing ESI and atmospheric pressure chemical ionization (APCI)].

### Synthesis Examples

The following compounds (1-1A) and (1-2A) were synthesized based on the method described in JP2010-18788A.

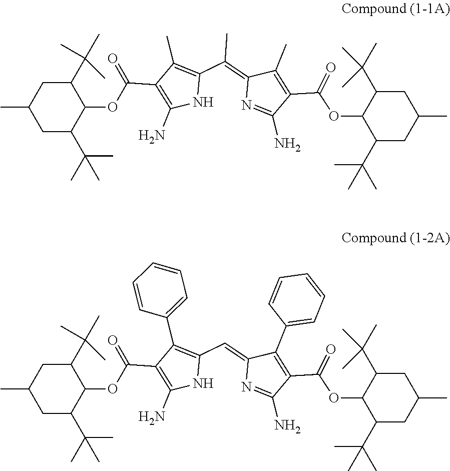

### Synthesis Example 1: Synthesis of Compound (1-1)

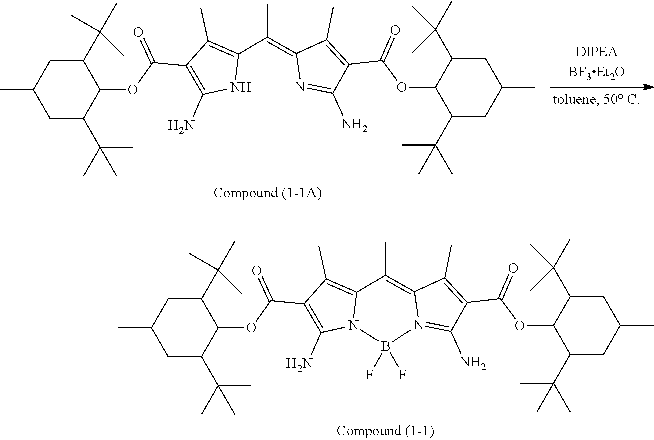

100 mg of the compound (1-1A), 5 ml of toluene, and a stirrer were put in a 100 ml three-neck flask, and the materials were stirred under a nitrogen atmosphere. 0.17 ml of N,N-diisopropylethylamine and 0.19 ml of boron trifluoride diethyl ether complex were added thereto and stirred for 2 hours at 50° C. to 55° C. After returning to room temperature, the resulting material was purified by silica gel column chromatography using hexane and ethyl acetate as an eluent to obtain 60 mg of the compound (1-1). Identification of the obtained compound was performed by LC-MS. [M+H⁺]⁺=769.5

### Synthesis Example 2: Synthesis of Compound (1-2)

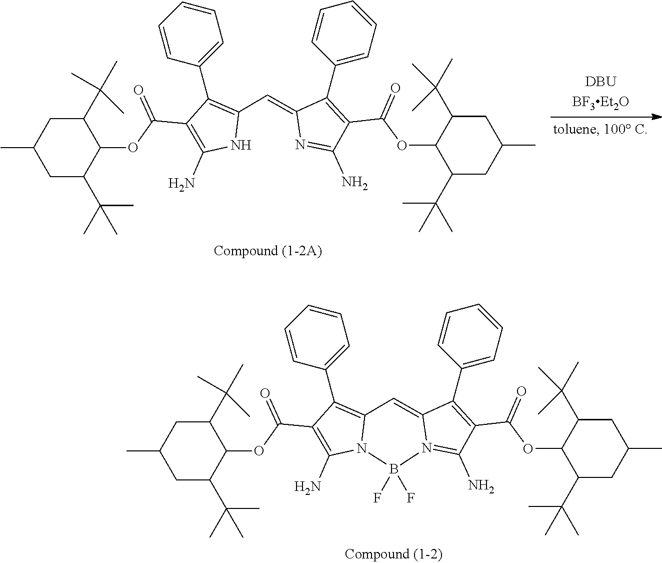

100 mg of the compound (1-2A), 5 ml of toluene, and a stirrer were put in a 100 ml three-neck flask, and the materials were stirred under a nitrogen atmosphere. 0.2 ml of 1,8-diazabicyclo[5.4.0]undec-7-ene and 0.2 ml of boron trifluoride diethyl ether complex were added thereto and stirred for 2 hours at 100° C. After returning to room temperature, the resulting material was purified by silica gel column chromatography using hexane and ethyl acetate as an eluent to obtain 30 mg of the compound (1-2). Identification of the obtained compound was performed by LC-MS. [M+H⁺]⁺=879.6

### Synthesis Example 3: Synthesis of Compound (2-1)

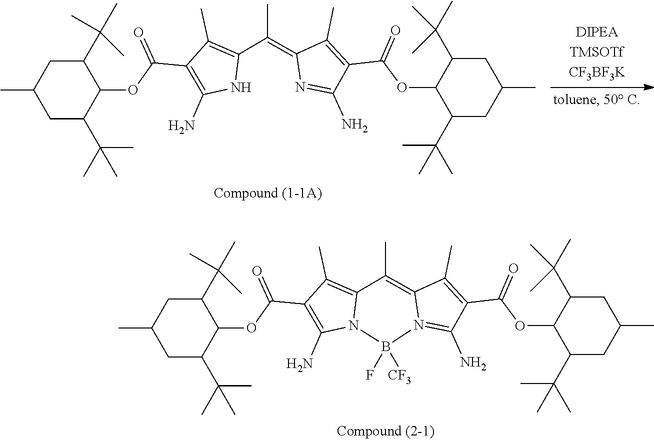

0.1 g of potassium trifluoro(trifluoromethyl)borate, 2 ml of acetonitrile, and 0.21 ml of trimethylsilyl trifluoromethanesulfonate were put in a 100 ml three-neck flask and stirred under a nitrogen atmosphere for 30 minutes or longer. Meanwhile, 100 mg of the compound (1-1A), 2.5 ml of dichloromethane, and 0.29 ml of N,N-diisopropylethylamine were added to a 100 ml three-neck flask, and a stirrer was put to stir the materials under nitrogen for 10 minutes or longer at room temperature. After that, these two solutions were cooled to 10° C. or lower, mixed, and reacted for 10 minutes at room temperature. Then, the temperature was returned to room temperature. An aqueous solution of sodium hydrogen carbonate was added, followed by extraction with dichloromethane and concentration of the organic layer under reduced pressure. The resulting material was purified by silica gel column chromatography using hexane and ethyl acetate as an eluent to obtain 40 mg of the compound (2-1). Identification of the obtained compound was performed by LC-MS. [M+H⁺]⁺=819.5

### Evaluation 1: Fluorescence Intensity of Fluorescent Latex

### Preparation of Fluorescent Latex Dispersion

Fluorescent latex particles were prepared as follows.

As latex particles, particles having an average particle diameter of 150 nm, which were prepared by polymerizing a mixture of styrene and an acrylic acid in a mass ratio of 9:1 in a state of being dispersed in water, were used. The average particle diameter was measured using a dynamic light scattering method using Zetasizer Nano ZS (trade name, manufactured by Malvern Panalytical Ltd.) based on the above-described measurement conditions. 5 mL of THF was added dropwise to 25 mL of the latex dispersion with a solid content of 2% (solid content mass: 500 mg) prepared as above, and the mixture was stirred for 10 minutes. 2.5 mL of a THF solution of a test compound (any one of the compound (1-1), the compound (1-2), the compound (2-1), or the comparative compound (1)) was added dropwise thereto for 15 minutes. The amounts of the compounds used for the respective samples were summarized in Table 1. In Table 1, μmol/g in the column of compound amount indicates the number of moles of the compound used with respect to 1 g of the solid content of the latex. Completion of the dropwise addition of the test compound was followed by stirring for 30 minutes and concentration under reduced pressure to remove THF. After that, the particles were precipitated by centrifugation, followed by addition of ultrapure water and redispersion to manufacture fluorescent latex dispersions Nos. 101 to 104, 201, 202, 301 to 303, and c11 to c14 with a concentration of solid contents of 2 mass %.

The average particle diameter of the prepared fluorescent latex particles measured in the same manner as the latex particles was 150 nm in any case.

### Evaluation of Fluorescent Latex Dispersion

The relative fluorescence intensity of the fluorescent latex dispersion with a concentration of solid contents of 2 mass % manufactured as above at an emission maximum wavelength was evaluated. The evaluation was performed using a latex dispersion diluted 200 times with ultrapure water with the use of a fluorescence spectrophotometer RF-5300PC (trade name) manufactured by Shimadzu Corporation for measurement of the emission maximum wavelength and the fluorescence intensity at the emission maximum wavelength.

In the respective test compounds, based on the fluorescence intensity at the emission maximum wavelength with a compound amount of 6 μmol/g, fluorescence intensities at the emission maximum wavelength with other compound amounts were evaluated as the relative fluorescence intensity. The results are summarized in Table 1.

TABLE 1

| | | Compound | |
|---|---|---|---|
| | | Amount | Relative |
| No. | Compound | (μmol/g) | Fluorescence Intensity |
| 101 | Compound (1-1) | 6 | (reference) |
| 102 | Compound (1-1) | 24 | 4 times as large as No. 101 |
| 103 | Compound (1-1) | 48 | 7 times as large as No. 101 |
| 104 | Compound (1-1) | 100 | 12 times as large as No. 101 |
| 201 | Compound (1-2) | 6 | (reference) |
| 202 | Compound (1-2) | 100 | 10 times as large as No. 201 |
| 301 | Compound (2-1) | 6 | (reference) |
| 302 | Compound (2-1) | 48 | 7 times as large as No. 301 |
| 303 | Compound (2-1) | 100 | 12 times as large as No. 301 |
| c11 | Comparative Compound (1) | 6 | (reference) |
| c12 | Comparative Compound (1) | 24 | 3 times as large as No. c11 |
| c13 | Comparative Compound (1) | 48 | 5 times as large as No. c11 |
| c14 | Comparative Compound (1) | 100 | 6 times as large as No. c11 |

From the results in Table 1, it has been found that in cases of the compounds (1-1), (1-2), and (2-1), which are compounds represented by General Formula (1) specified in the present invention, a fluorescent latex which exhibits a higher fluorescence intensity as the compound amount is increased is obtained than in case of the comparative compound (1).

In this way, in case of the compound represented by General Formula (1) specified in the present invention, in a case where a fluorescent latex is prepared, it is possible to obtain a fluorescent latex which exhibits a higher fluorescence intensity and higher luminance as the concentration of the compound to be blended is increased than in case of the compound not represented by General Formula (1) specified in the present invention. This is thought to be based on the fact that the association of the compound in the latex particles is suppressed due to the partial structure represented by Formula (A) included in the compound represented by General Formula (1) specified in the present invention.

### EXAMPLES

### Example 1

30 g of polystyrene (trade name: PSJ-polystyrene SGP-10, manufactured by PS Japan Corporation) was dissolved in 70 g of methylene chloride, and then 11.6 mg of the compound (1-1) (the number of moles of the compound per 1 g of solid contents in the composition was 0.5 μmol/g) was added to prepare a material for wavelength conversion (composition (solution) for wavelength conversion).

Then, a glass plate was spin-coated with the composition for wavelength conversion by 2,000 rotations, and dried on a hot plate at 100° C. to prepare a film-shaped material for wavelength conversion (wavelength conversion member). The thickness of the obtained wavelength conversion layer was 60 μm.

### Example 2

Cellulose acylate having an acetyl substitution degree of 2.87 was prepared as follows. First, 7.8 parts by mass of a sulfuric acid as a catalyst was added with respect to 100 parts by mass of cellulose, a carboxylic acid as a raw material of an acyl substituent was added thereto, and an acylation reaction was performed at 40° C. After the acylation, the product was left to age at 40° C. Furthermore, the cellulose acylate was washed using acetone so as to remove low molecular weight components.

Thereafter, 30 g of the cellulose acylate was dissolved in 170 g of a mixed solvent of methylene chloride and methanol (mass ratio 87:13), and then 11.6 mg of the compound (1-1) (the number of moles of the compound per 1 g of solid contents in the composition was 0.5 μmol/g) was added to prepare a material for wavelength conversion (composition (solution) for wavelength conversion).

Then, a glass plate was spin-coated with the composition for wavelength conversion by 2,000 rotations, and dried on a hot plate at 140° C. to prepare a film-shaped material for wavelength conversion (wavelength conversion member). The thickness of the obtained wavelength conversion layer was 60 μm.

### Example 3

30 g of polymethyl methacrylate (manufactured by Sigma-Aldrich Co. LLC, referred to as methacrylic resin in the table) was dissolved in 300 mL of toluene, and then 11.6 mg of the compound (1-1) (the number of moles of the compound per 1 g of solid contents in the composition was 0.5 μmol/g) was added to prepare a material for wavelength conversion (composition (solution) for wavelength conversion).

Then, a glass plate was spin-coated with the composition for wavelength conversion by 2,000 rotations, and dried on a hot plate at 50° C. to prepare a film-shaped material for wavelength conversion (wavelength conversion member). The thickness of the obtained wavelength conversion layer was 60 μm.

### Example 4

15 g of a solution A and 15 g of a solution B of a silicone resin (trade name: KER-2500, dual component addition curing type, manufactured by Shin-Etsu Chemical Co., Ltd.) were mixed together, and then 11.6 mg of the compound (1-1) (the number of moles of the compound per 1 g of solid contents in the composition was 0.5 μmol/g) was added thereto. These were mixed using a rotation/revolution mixer (manufactured by THINKY CORPORATION, trade name: AWATORI RENTARO) at 2,000 rpm (rotation per minute) and defoamed at 2,200 rpm. In this way, a material for wavelength conversion (composition (solution) for wavelength conversion) was prepared.

Thereafter, a glass plate was coated with the composition for wavelength conversion and heated on a hot plate at 60° C. for 2 hours and then at 150° C. for 4 hours so as to cure the composition. In this way, a film-shaped material for wavelength conversion (wavelength conversion member) was prepared. The thickness of the obtained wavelength conversion layer was 60 μm.

### Examples 5 and 6 and Comparative Examples 1 to 3

Compositions (solutions) for wavelength conversion in which the number of moles of the compound per 1 g of solid contents in the composition was 0.5 μmol/g and film-shaped wavelength conversion members were prepared in the same manner as in Example 1, except that in the preparation of the composition (solution) for wavelength conversion and the wavelength conversion member in Example 1, the compounds shown in Table 2 were used instead of the compound (1-1). The thicknesses of the obtained wavelength conversion layers were all 60 μm.

### Evaluation 2: Evaluation of Material for Wavelength Conversion

The absorption characteristics of each compound, and the quantum yield, wavelength conversion performance, and moist heat resistance of the prepared film-shaped wavelength conversion member (wavelength conversion layer) were evaluated as follows. The obtained results are summarized in Table 2.

### Evaluation of Absorption Characteristics of Compound

Using a spectrophotometer UV-3600 (trade name) manufactured by Shimadzu Corporation, a molar absorption coefficient ϵ (1/mol·cm) and a half-width at a maximal absorption wavelength were measured and evaluated based on the following evaluation ranks. The half-width means a width (distance) between two wavelengths showing half the intensity of the maximal value at the maximum absorption wavelength. In the table, the evaluation of the molar absorption coefficient ϵ is described in the column of ϵ. As a measurement solvent, chloroform was used.

In this test, a molar absorption coefficient at evaluation rank “B” or higher (S to B) is regarded as acceptable, and due to the fact that the half-width is preferably narrow from the viewpoint of an improvement of color reproducibility, a half-width at evaluation rank “A” or higher (S or A) is regarded as acceptable.

### Evaluation Ranks of Molar Absorption Coefficient ϵ

S: equal to or greater than 130,000

A: equal to or greater than 120,000 and less than 130,000

B: equal to or greater than 110,000 and less than 120,000

C: equal to or greater than 100,000 and less than 110,000

D: less than 100,000

In the above evaluation ranks, the unit of ϵ is 1/mol·cm.

### Evaluation Ranks of Half-Width

S: equal to or less than 30 nm

A: equal to or greater than 31 nm and equal to or less than 35 nm

B: equal to or greater than 36 nm and equal to or less than 40 nm

C: equal to or greater than 41 nm

In the above evaluation ranks, the half-width is a value rounded off to the nearest whole number.

### Measurement of Quantum Yield

The prepared film-shaped wavelength conversion member was cut into a square size of 15 mm×15 mm to obtain a test piece (with a glass plate). The quantum yield of the test piece was measured using an absolute PL quantum yield measuring device C9920-02 (trade name, manufactured by Hamamatsu Photonics K.K.). The excitation wavelength was set to a wavelength 50 nm shorter than the maximum absorption wavelength of the compound used for each of the wavelength conversion members. The quantum yields of the film-shaped wavelength conversion members of Examples 1 to 6 were all 0.7 or more, which were almost the same as those of the film-shaped materials for wavelength conversion of Comparative Examples 1 to 3, and the members exhibited a sufficient quantum yield as a material for wavelength conversion.

### Evaluation of Wavelength Conversion Performance

The prepared film-shaped wavelength conversion member was cut into a square size of 15 mm×15 mm to obtain a test piece. An emission spectrum of the test piece was measured using a fluorescence spectrophotometer RF-5300PC (trade name, manufactured by Shimadzu Corporation).

The wavelength conversion performance was evaluated by evaluating the maximum wavelength of the emission spectrum based on the following evaluation ranks. In a case where the emission maximum wavelength is at evaluation rank “B” or higher, it is shown that the material for wavelength conversion and the wavelength conversion member are suitable as a material for wavelength conversion and a wavelength conversion member capable of converting incoming rays into red light emission, respectively.

### Evaluation Ranks of Emission Maximum Wavelength

AA: equal to or greater than 600 nm and less than 650 nm

A: equal to or greater than 580 nm and less than 600 nm

B: equal to or greater than 560 nm and less than 580 nm

C: equal to or greater than 540 nm and less than 560 nm

D: equal to or greater than 520 nm and less than 540 nm

E: equal to or greater than 480 nm and less than 520 nm

### Moist Heat Resistance Test

The prepared film-shaped wavelength conversion member was cut into a square size of 40 mm×40 mm to obtain a test piece. The test piece was stored under the following test conditions in a thermohygrostat (trade name: ESPEC CORP PR-4T, manufactured by ESPEC CORP.).

The absorbance at a maximal absorption wavelength before and after storage was measured using a spectrophotometer UV3150 (trade name, manufactured by Shimadzu Corporation). As an absorbance retention rate after lapse of 7 days, a percentage of the absorbance after storage at the maximal absorption wavelength to the absorbance before storage at the maximal absorption wavelength ([absorbance after storage at maximal absorption wavelength/absorbance before storage at maximal absorption wavelength]×100) was calculated, and the obtained absorbance retention rate was evaluated based on the following evaluation ranks.

In this test, moist heat resistance at evaluation rank “C” or higher (A to C) is regarded as acceptable.

### Test Conditions

Storage Time: 7 days

Set Temperature: 85° C.

Set Humidity: 85 RH %

### Evaluation Ranks

A: equal to or greater than 80%

B: equal to or greater than 70% and less than 80%

C: equal to or greater than 60% and less than 70%

D: equal to or greater than 50% and less than 60%

E: less than 50%

TABLE 2

| | | | | | Wavelength | Moist |
|---|---|---|---|---|---|---|
| | | | | | Conversion | Heat |
| | Compound | Resin | ε | Half-Width | Performance | Resistance |
| Example 1 | Compound (1-1) | Polystyrene | S | S | B | A |
| | | Cellulose | | | | |
| Example 2 | Compound (1-1) | Acylate | S | S | B | A |
| Example 3 | Compound (1-1) | Methacrylic | S | S | B | A |
| | | Resin | | | | |
| Example 4 | Compound (1-1) | Silicone Resin | S | S | B | A |
| Example 5 | Compound (1-2) | Polystyrene | S | A | AA | A |
| Example 6 | Compound (2-1) | Polystyrene | S | S | B | A |
| Comparative | Comparative | Polystyrene | D | S | D | A |
| Example 1 | Compound (1) | | | | | |
| Comparative | Comparative | Polystyrene | C | A | C | A |
| Example 2 | Compound (2) | | | | | |
| Comparative | Comparative | Polystyrene | D | C | AA | A |
| Example 3 | Compound (3) | | | | | |

From the results shown in Table 2, the followings are found.

In all the compositions for wavelength conversion or wavelength conversion members of Comparative Examples containing no compound represented by General Formula (1) specified in the present invention, the molar absorption coefficient of the compound was small.

In contrast, it has been found that all the compositions for wavelength conversion or wavelength conversion members containing the compound represented by General Formula (1) specified in the present invention have a large molar absorption coefficient and exhibit more excellent wavelength conversion efficiency than Comparative Examples, while maintaining almost the same quantum yield as Comparative Examples. That is, even in a case where the compositions for wavelength conversion and the wavelength conversion members of Examples are in the form of a solution composition or in the form of a film-shaped wavelength conversion member (solid composition) as a mixture with a binder resin, the molar absorption coefficient is significantly improved while the quantum yield is maintained as in the related art, whereby an excellent wavelength conversion function is exhibited. Moreover, the compositions for wavelength conversion and the wavelength conversion members of Examples also show excellent wavelength conversion performance to red.

### Evaluation 3: Solubility of Compound

### Solubility

The solubility in the following solvents or media A to G as raw material monomers of a resin was evaluated. The evaluation method is as follows: 0.1 ml of a solvent was added to 1 gmg of each compound to dissolve the compound, and the solubility was visually determined based on the following evaluation ranks. In this test, evaluation rank “B” or higher is an acceptable level.

### Evaluation Ranks

A: completely melted

B: mostly dissolved

C: slightly dissolved

D: mostly insoluble

TABLE 3

| | Medium A | Medium B | Medium C | Medium D | Medium E | Medium F | Medium G |
|---|---|---|---|---|---|---|---|
| Compound (1-1) | A | B | A | A | A | A | B |
| Compound (2-1) | A | B | A | A | A | A | B |
| Comparative | B | C | C | C | D | D | D |
| Compound (1) | | | | | | | |

Notes of Table
Medium A: ethyl acetate
Medium B: toluene
Medium C: 2-phenoxyethyl acrylate
Medium D: cyclohexyl acrylate
Medium E: isobornyl acrylate
Medium F: tetrahydrofurfuryl acrylate
Medium G: 1,6-hexanediol diacrylate

From the results shown in Table 3, the followings are found.

The comparative compound (1), which is not a compound represented by General Formula (1) specified in the present invention, had poor solubility in the solvent or raw material monomer.

In contrast, both the compounds (1-1) and (2-1), which are compounds represented by General Formula (1) specified in the present invention, had excellent solubility in the solvent or raw material monomer.

From the results, the compound represented by General Formula (1) specified in the present invention has a larger molar absorption coefficient and more excellent solubility than a dipyrromethene boron complex compound according to the related art. In the material for wavelength conversion and the wavelength conversion member according to the embodiment of the present invention containing the compound represented by General Formula (1), it is easy to make the compound represented by General Formula (1) more uniformly exist at a higher concentration in the material for wavelength conversion, and a material for wavelength conversion and a wavelength conversion member having high luminance can be obtained.

What is claimed is:

1. A material for wavelength conversion comprising:
a compound represented by General Formula (1), 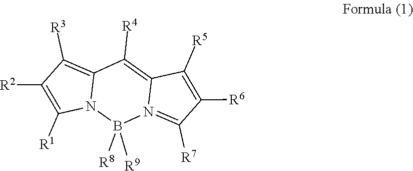
in the formula, R¹ to R⁷ each represent a hydrogen atom or a substituent, and R⁸ and R⁹ each represent an alkyl group, a cycloalkyl group, an aliphatic heterocyclic group, an alkenyl group, a cycloalkenyl group, an alkynyl group, a hydroxy group, a sulfanyl group, an alkoxy group, an alkylthio group, an aryloxy group, an arylthio group, an aryl group, a heteroaryl group, a cyano group, or a halogen atom,
provided that at least one of R¹, . . . , or R⁹ has a partial structure represented by Formula (A), 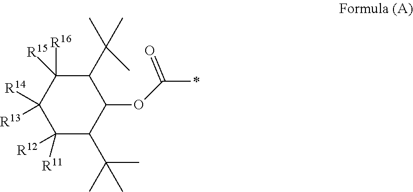
in the formula, R¹¹ to R¹⁶ each represent a hydrogen atom or an alkyl group, and the symbol * represents a bonding site.

2. The material for wavelength conversion according to claim 1,
wherein the compound represented by General Formula (1) is a compound represented by General Formula (2) or (3), 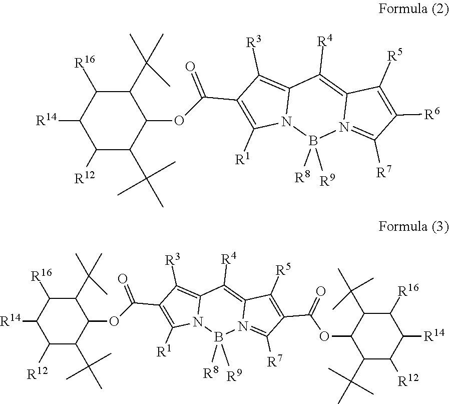
in the formula, R¹, R³ to R⁹, R¹², R¹⁴, and R¹⁶ have the same definition as R¹, R³ to R⁹, R¹², R¹⁴, and R¹⁶ described above, respectively.

3. The material for wavelength conversion according to claim 1,
wherein at least one of R⁸ or R⁹ is a halogenated alkyl group, a halogenated alkyloxy group, or a cyano group.

4. A wavelength conversion member comprising:
a wavelength conversion portion formed of the material for wavelength conversion according to claim 1.

5. A light emitting device comprising:
a light source; and
the wavelength conversion member according to claim 4, which converts light emitted from the light source.

6. The light emitting device according to claim 5,
wherein the light emitting device is a display device or a lighting device.

7. The light emitting device according to claim 6,
wherein the display device is a liquid crystal display device.

8. A compound represented by General Formula (1A), 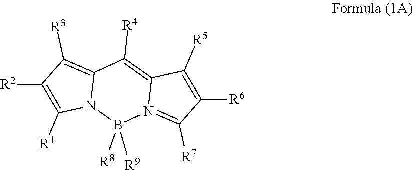
in the formula, R¹ to R⁷ each represent a hydrogen atom or a substituent, and R⁸ and R⁹ each represent an alkyl group, a cycloalkyl group, an aliphatic heterocyclic group, an alkenyl group, a cycloalkenyl group, an alkynyl group, a hydroxy group, a sulfanyl group, an alkoxy group, an alkylthio group, an aryloxy group, an arylthio group, an aryl group, a heteroaryl group, a cyano group, or a halogen atom,
provided that at least one of R⁸ or R⁹ is a halogenated alkyl group, a halogenated alkyloxy group, or a cyano group, and at least one of R¹, . . . , or R⁹ has a partial structure represented by Formula (A), 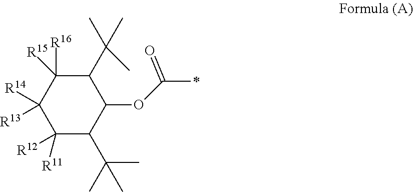
in the formula, R¹¹ to R¹⁶ each represent a hydrogen atom or an alkyl group, and the symbol * represents a bonding site.

9. The compound according to claim 8,
wherein the compound is a compound represented by General Formula (2A) or (3A), 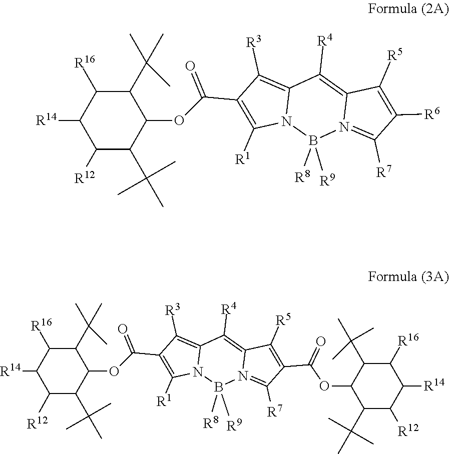
in the formula, R¹, R³ to R⁹, R¹², R¹⁴, and R¹⁶ have the same definition as R¹, R³ to R⁹, R¹², R¹⁴, and R¹⁶ described above, respectively.

10. The compound according to claim 8,
wherein at least one of R⁸ or R⁹ is a halogenated alkyl group or a cyano group.
